(19) United States
(12) Patent Application Publication
(10) Pub. No.: US 2026/0247748 A1
(43) Pub. Date: Aug. 20, 2026

(54) SYSTEM AND METHOD FOR MICRO-LED OPTICAL INTERCONNECTS

(71) Applicant: Density AI, Inc., Mountain View, CA (US)

(72) Inventors: Nachiket Raravikar, Mountain View, CA (US); Ron Rosenberg, Mountain View, CA (US); William Chang, Mountain View, CA (US); Sameet Ramakrishnan, Mountain View, CA (US)

(21) Appl. No.: 19/544,683

(22) Filed: Feb. 19, 2026

Related U.S. Application Data
(60) Provisional application No. 63/760,854, filed on Feb. 20, 2025.
(60) Provisional application No. 63/767,217, filed on Mar. 5, 2025.
(60) Provisional application No. 63/912,142, filed on Nov. 5, 2025.
(60) Provisional application No. 63/912,152, filed on Nov. 5, 2025.

(51) Int. Cl. H10H 20/814; G02B 6/12; H10H 20/01; H10H 20/812; H10H 20/813; H10H 20/816; H10H 20/821; H10H 20/825; H10H 20/833; H10H 20/841

(52) U.S. Cl. CPC H10H 20/814; G02B 6/12; H10H 20/0137; H10H 20/017; H10H 20/032; H10H 20/034; H10H 20/0363; H10H 20/812; H10H 20/8133; H10H 20/8162; H10H 20/821; H10H 20/8252; H10H 20/833; H10H 20/841; G02B 2006/12104; G02B 2006/12123

(57) ABSTRACT

Provided is a structure for a micro-light-emitting diode, including a substrate layer, an n-type GaN layer disposed above the substrate layer, the n-type GaN layer including a donor selected from silicon and germanium, an active region disposed above the n-type GaN layer, the active region including a multiple-quantum-well stack of InGaN quantum wells separated by barrier layers, each quantum well having a thickness of less than or equal to 3 nanometers and at least one of the quantum wells having an indium mole fraction greater than 0.10, an electron blocking layer disposed above the active region, the electron blocking layer including an aluminum-containing group-III nitride, a p-type GaN layer disposed above the electron blocking layer, and an epitaxial optical reflector disposed relative to the active region including at least one of a distributed Bragg reflector below the active region, and a distributed Bragg reflector above the active region.

### CROSS-REFERENCE TO RELATED APPLICATIONS

This patent claims the benefit of U.S. Provisional Patent Application 63/760,854, filed Feb. 20, 2025, titled MICRO-LED OPTICAL INTERCONNECTS FOR WAFER-SCALE COMPUTING SYSTEMS AND METHODS FOR MAKING THE SAME, U.S. Provisional Patent Application 63/767,217, filed Mar. 5, 2025, titled ALL-TO-ALL DIE-TO-DIE OPTICAL INTERCONNECT NETWORK USING MULTI-LAYER WAVEGUIDE STRUCTURES, U.S. Provisional Patent Application 63/912,152, filed Nov. 5, 2025, titled SUPER-LUMINESCENT LEDS WITH ASYMMETRIC CAVITIES FOR OPTICAL INTERCONNECTS, and U.S. Provisional Patent Application 63/912,142, filed Nov. 5, 2025, titled SEMIPOLAR AND NON-POLAR GAN NANOWIRE LIGHT EMITTING DEVICES. The entire content of each afore-listed earlier-filed application is hereby incorporated by reference for all purposes.

### BACKGROUND

### 1. Field

The present disclosure relates generally to micro-LED-based optical interconnects for high-speed semiconductor communication.

### 2. Description of the Related Art

Interconnect architectures support communication among processing resources, memory resources, and peripheral interfaces. As workloads scale in artificial intelligence and high-performance computing, electrical links may encounter bandwidth density constraints, higher energy cost associated with high-speed signaling, and degradation of signal integrity as transmission distance increases. Approaches such as serializer/deserializer interfaces, wide parallel buses, and silicon-photonics links may address portions of these challenges, yet each can introduce trade-offs, including elevated power draw, restricted communication distance for a given footprint, and reliance on off-chip light sources with associated packaging, thermal, and reliability considerations. There remains interest in interconnect technologies that provide high data throughput with reduced energy cost while supporting transmission over practical distances and remaining compatible with wafer-scale or panel-scale manufacturing flows.

Micro-light-emitting diode-based optical links have been investigated as an alternative pathway for on-package and chip-to-chip communication. Because emission can be generated within a semiconductor stack, such links may support distributed optical transmitters without external laser assemblies. However, device structures that have been developed for image display applications may utilize pixel geometries and active-region configurations that are not tailored for high-speed modulation, nor optimized for efficient coupling to optical paths that must extend over the distances required for interconnect applications. Accordingly, improved emitter structures and pixel geometries that are configured for communication-centric performance would be advantageous.

### SUMMARY

The following is a non-exhaustive listing of some aspects of the present techniques. These and other aspects are described in the following disclosure.

Some aspects include a structure for a micro-light-emitting diode, including a substrate layer, an n-type GaN layer disposed above the substrate layer, the n-type GaN layer including a donor selected from silicon and germanium, an active region disposed above the n-type GaN layer, the active region including a multiple-quantum-well stack of InGaN quantum wells separated by barrier layers, each quantum well having a thickness of less than or equal to 3 nanometers and at least one of the quantum wells having an indium mole fraction greater than 0.10, an electron blocking layer disposed above the active region, the electron blocking layer including an aluminum-containing group-III nitride, a p-type GaN layer disposed above the electron blocking layer, and an epitaxial optical reflector disposed relative to the active region including at least one of a distributed Bragg reflector below the active region, and a distributed Bragg reflector above the active region.

Some aspects include a pixel structure of a micro-light-emitting diode device including a mesa defined by etching through a p-type GaN layer of an epitaxial stack and at least partially into an InGaN active region of the epitaxial stack, the mesa having a lateral dimension less than 15 micrometers, wherein sidewalls of the mesa have a tapered, conical, or parabolic profile, isolation trenches extending through the epitaxial stack laterally bounding the mesa, a conformal dielectric passivation layer on the sidewalls of the mesa, a transparent conductive current-spreading layer over the mesa, a reflector over the transparent conductive current-spreading layer, an adhesion/barrier stack between the reflector and the transparent conductive current-spreading layer, a planarization dielectric surrounding the mesa, the planarization dielectric including vias to the transparent conductive current-spreading layer and to an n-type GaN layer of the epitaxial stack, a p-contact metallization coupled to the transparent conductive current-spreading layer, an n-contact metallization coupled to the n-type GaN layer, the n-contact at least partly surrounding the mesa, an anti-reflection coating disposed on the reflector, and an emission-collimation feature aligned to the mesa including one of a micro-lens, or a surface-textured region configured to increase coupling of emitted light.

Some aspects of the disclosure relate to micro-light-emitting-diode (micro-LED) optical interconnect technology for on-package and chip-to-chip communication. In some embodiments, the disclosed system may integrate fast-switching GaN-based micro-LED emitters, GaN-or silicon-based photodiodes, and waveguide-coupled interposers to provide scalable optical links with low energy per bit and high bandwidth density while maintaining compatibility with wafer-scale or panel-scale manufacturing. In some embodiments, light emission may be generated within a semiconductor stack and driven on a per-emitter basis, which may reduce power usage and integration complexity and support dense, distributed transmitters.

In some embodiments, the micro-LED may be fabricated on c-plane GaN, m-plane GaN, or other semi-polar or non-polar GaN orientations, with the orientation selected based on its impact on carrier transport, internal quantum efficiency, and emission characteristics. The device architecture may be organized along two complementary axes. An epitaxial design pertains to the layered III-nitride structure (e.g., substrate, n-type GaN, multiple-quantum-well active region, electron blocking layer, and p-type GaN) where material composition, doping, and thickness profiles may be selected to support high-speed modulation and efficient recombination. A pixel design may pertain to the emission unit geometry and overlying features (e.g., mesa shaping, sidewall passivation, transparent current-spreading layers, reflectors, and contact topology) selected to enhance external quantum efficiency and optical coupling to integrated waveguides.

### BRIEF DESCRIPTION OF THE DRAWINGS

The above-mentioned aspects and other aspects of the present techniques will be better understood when the present application is read in view of the following figures in which like numbers indicate similar or identical elements:

FIG. 1 illustrates a cross-sectional view of an epitaxially grown micro-light-emitting diode structure including multiple semiconductor layers.

FIG. 2 illustrates a cross-sectional view of a micro-light-emitting diode pixel defined from the epitaxial structure, including a substrate and electrical contacts.

FIGS. 3A-3D illustrate cross-sectional views of example optical-electrical chiplet configurations showing different interconnection arrangements.

FIGS. 4A-4C illustrate block diagrams of example integration schemes including optical-electrical chiplets, processing units, memory modules, and waveguides configured to provide optical and electrical interconnects.

FIG. 5 is a block diagram of a method of fabricating an epitaxial micro-light-emitting diode structure.

FIG. 6 is a block diagram of a method of forming a micro-light-emitting diode pixel structure including contact formation.

FIGS. 7A-7B illustrate cross-sectional schematic views of a micro-LED pixel optically coupled to a waveguide using an external lens and a GaN-formed lens.

FIG. 8 illustrates an exemplary computer system configured to implement aspects of the present techniques.

While the present techniques are susceptible to various modifications and alternative forms, specific embodiments thereof are shown by way of example in the drawings and will herein be described in detail. The drawings may not be to scale. It should be understood, however, that the drawings and detailed description thereto are not intended to limit the present techniques to the particular form disclosed, but to the contrary, the intention is to cover all modifications, equivalents, and alternatives falling within the spirit and scope of the present techniques as defined by the appended claims.

### DETAILED DESCRIPTION OF CERTAIN EMBODIMENTS

To mitigate the problems described herein, the inventors had to both invent solutions and, in some cases just as importantly, recognize problems overlooked (or not yet foreseen) by others in the field of micro-LED-based optical interconnects for high-speed semiconductor communication. Indeed, the inventors wish to emphasize the difficulty of recognizing those problems that are nascent and will become much more apparent in the future should trends in industry continue as the inventors expect. Further, because multiple problems are addressed, it should be understood that some embodiments are problem-specific, and not all embodiments address every problem with traditional systems described herein or provide every benefit described herein. That said, improvements that solve various permutations of these problems are described below.

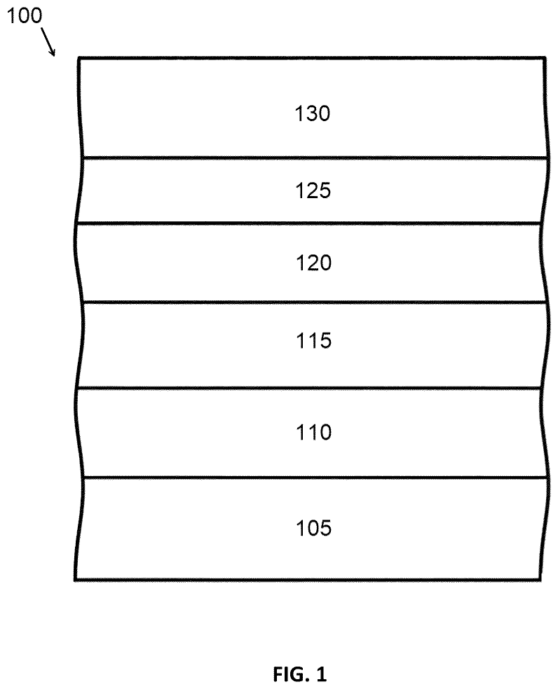

FIG. 1 illustrates an example epitaxial structure 100 for a micro-light-emitting diode. The structure may include a series of layers formed on a substrate and configured to provide optical emission when electrically biased. The drawing is provided for conceptual clarity, and the relative thicknesses of the illustrated layers are not intended to correspond to actual layer dimensions in a fabricated device. In practice, each layer may have a thickness selected according to epitaxial growth conditions and desired device performance, and some layers may be orders of magnitude thicker or thinner than others.

In some embodiments, epitaxial structure 100 may include a substrate layer 105 that supports subsequent III-nitride growth. A growth seed layer 110 may be provided on the substrate layer 105 to initiate crystalline growth and manage lattice mismatch. An n-type gallium nitride (GaN) layer 115 may be formed on the growth seed layer 110 to provide a lower cladding and current-spreading region. An active region 120 may be disposed above the n-type GaN layer and may comprise a multiple-quantum-well (MQW) stack of InGaN quantum wells separated by barrier layers, configured to emit photons upon recombination of carriers. An electron blocking layer (EBL) 125 may be formed above the active region 120 to limit electron overflow into upper layers and thereby improve recombination efficiency within the active region. A p-type GaN layer 130 may be disposed over the electron blocking layer 125 to provide a hole-injection layer and upper cladding for the device. In some embodiments, the p-type GaN layer 130 may further include a highly doped contact cap to facilitate subsequent metallization steps, although such a feature is not required for all configurations.

In some embodiments, substrate layer 105 may comprise a crystalline platform selected from silicon, sapphire, silicon carbide, or gallium nitride and may be configured to support high-quality III-nitride epitaxy. The substrate may be selected based on lattice and thermal expansion compatibility, thermal conductivity, manufacturability, and availability at wafer diameters including 50 mm, 100 mm, 200 mm, or 300 mm. When the substrate comprises gallium nitride, a surface orientation such as c-plane, m-plane, semi-polar, or non-polar may be selected to influence carrier transport, polarization behavior, and optical extraction.

In some embodiments, substrate layer 105 may include a controlled miscut and surface preparation to promote step-flow growth and may be processed to provide surface morphology and contamination levels compatible with subsequent epitaxy. The substrate may function as a mechanical support and a thermal pathway during operation and may be configured to accommodate downstream singulation or integration with interposers or chiplet assemblies.

In some embodiments, growth seed layer 110 may be disposed on substrate layer 105 and may comprise one or more films configured to initiate III-nitride nucleation and manage strain during subsequent growth. The growth seed layer 110 may include a low-temperature nucleation film and a higher-temperature buffer and may further include dislocation-reduction structures such as superlattices or graded-composition layers to reduce threading dislocation density. In embodiments where the substrate comprises silicon, the growth seed layer 110 may include an aluminum-containing transition layer to limit interfacial reactions and accommodate thermal expansion differences. The growth seed layer 110 may be undoped or lightly doped and may be formed using metal-organic chemical vapor deposition or molecular beam epitaxy with process conditions selected to provide a smooth surface and crystallographic registry suitable for formation of n-type gallium nitride layer 115. In some embodiments, the growth seed layer 110 may include a low-temperature nucleation film having a thickness of about 10 to 50 nanometers and a strain-management buffer having a thickness of about 0.1 to 2.0 micrometers. The strain-management buffer may include a dislocation-reduction superlattice with a period thickness of about 1 to 10 nanometers repeated for about 5 to 50 periods.

In some embodiments, n-type gallium nitride layer 115 may be disposed over growth seed layer 110 and may function as an electron-conducting region and lower optical cladding for active region 120. The n-type gallium nitride may comprise a donor dopant such as silicon or germanium at a concentration suitable to provide low series resistance and lateral current spreading for micro-scale pixels, and may be formed to a micrometer-scale thickness selected in view of substrate thermal properties and downstream contact geometry. In some embodiments, the layer may be grown by metal-organic chemical vapor deposition or molecular beam epitaxy using process conditions selected to promote low threading dislocation density and a smooth surface morphology prepared for subsequent quantum-well formation. In some embodiments, the n-type gallium nitride layer 115 may have a thickness of about 0.5 to 5.0 micrometers. The n-type gallium nitride layer 115 may be formed with a surface roughness compatible with subsequent active-region formation and with a doping distribution selected to provide lateral current spreading at micro-scale pixel dimensions.

In some embodiments, n-type gallium nitride layer 115 may include a doping profile that is uniform or graded in proximity to active region 120 to manage band alignment and polarization charge, and may be paired with one or more dislocation-reduction or cladding sublayers to improve crystalline quality. The upper surface of n-type gallium nitride layer 115 may be conditioned to provide a clean interface to active region 120, and background impurities may be controlled to limit compensation and junction leakage. The layer may be configured to provide access for later n-contact formation, including perimeter contacts or vias to buried regions when integrated with chiplet or interposer assemblies.

In some embodiments, the active region 120 may comprise a multiple-quantum-well stack disposed between the n-type gallium nitride layer 115 and the electron blocking layer 125. The wells may include indium gallium nitride with an indium mole fraction selected to set the emission band and to increase electron-hole wavefunction overlap, and the barriers may include gallium nitride, aluminum gallium nitride, or indium gallium nitride having a reduced indium content relative to the wells. In some embodiments, the active region 120 may comprise a multiple-quantum-well stack having a well thickness of about 1.0 to 3.0 nanometers and a barrier thickness of about 2 to 15 nanometers, with a well count of about 2 to 10. At least one well may include an indium mole fraction greater than 0.10. Barriers may comprise gallium nitride, aluminum gallium nitride, or indium gallium nitride having a reduced indium content relative to the wells. Barrier thickness and composition may be selected to manage inter-well coupling, and asymmetry may be introduced between lower and upper barriers to shape capture dynamics and to reduce spill-over toward the electron blocking layer 125.

In some embodiments, the multiple-quantum-well stack may incorporate superlattice layering to tune band offsets, mitigate strain, and manage polarization fields. The barriers may be implemented as short-period digital alloys formed by alternating nitride monolayers (e.g., GaN/AlGaN or low-In/high-In InGaN periods) to realize an effective alloy with engineered conduction-and valence-band profiles while maintaining abrupt interfaces. A strain-balancing superlattice may be inserted adjacent to one or more wells to reduce threading dislocation propagation and to moderate piezoelectric fields across the active region 120. One or more ultra-thin interlayers having aluminum content greater than neighboring layers may be included to increase electron confinement without materially increasing series resistance, and a cap above the uppermost well may be selected to establish a controlled spacing to the electron blocking layer 125 for high-frequency modulation.

In some embodiments, growth of the multiple-quantum-well stack and any associated superlattice layering may be performed by metal-organic chemical vapor deposition or molecular beam epitaxy using precursor sequences selected to promote uniform thickness, composition, and interface abruptness at wafer scale. Temperature or precursor-flow modulations may be used to control indium incorporation and to limit phase separation. Brief growth interrupts, migration-assisted steps, and surface treatments may be employed to sharpen interfaces and to reduce interface roughness. The wells may be undoped or lightly doped to suppress non-radiative pathways, and background impurities may be controlled to limit compensation. Crystallographic orientation may be selected to tune polarization-induced fields. Semi-polar or non-polar orientations may be used to reduce quantum-confined Stark effects, while c-plane orientations may be paired with compositional grading within wells or superlattice barriers to temper internal fields.

In some embodiments, the active region 120 may comprise a quantum-dot superlattice in place of the multiple-quantum-well stack. The quantum-dot superlattice may include indium-containing III-nitride islands embedded within a matrix such as aluminum indium gallium nitride or gallium nitride, providing three-dimensional carrier confinement and spectral control. Dot areal density, lateral size distribution, and vertical periodicity may be selected by growth temperature, group-III supply, and nitrogen activity to influence radiative rates and emission bandwidth, and spacer layers may be deposited to set electronic coupling between dot planes. In some embodiments where the active region 120 is implemented as a quantum-dot superlattice, dot height may be about 1 to 5 nanometers, lateral dot size may be about 3 to 20 nanometers, dot areal density may be about 1×10⁹ to 1×10¹¹ cm⁻², spacer thickness between dot planes may be about 3 to 10 nanometers, and the number of dot/spacer periods may be about 2 to 20. The matrix composition may be selected to provide a bandgap contrast sufficient for three-dimensional carrier confinement.

In some embodiments, a hybrid active region may be implemented that combines multiple-quantum-well and quantum-dot superlattice layering. A dots-in-a-well configuration may embed a quantum-dot plane within at least one indium gallium nitride quantum well of the stack to increase local confinement while preserving lateral current spreading. An alternating sequence may be used in which a quantum-well period and a quantum-dot plane separated by a spacer are repeated to a selected count to tailor gain spectrum and modulation response. Stacked sub-sections may place an MQW sub-stack closer to the n-type gallium nitride layer 115 and a quantum-dot superlattice closer to the electron blocking layer 125, or vice versa, with spacing and composition selected to control carrier capture, recombination zones, and internal field distribution.

In some embodiments, the hybrid structure may be grown using coordinated process windows for both quantum-well and quantum-dot formation so that interface abruptness, dot statistics, and well thickness remain uniform across die intended for chiplet assemblies. The matrix and barrier compositions may be selected to provide bandgap contrast sufficient to confine carriers within wells and dot planes while maintaining a low-resistance path through adjacent cladding. The active region 120 may be configured to cooperate with downstream pixel geometries, sidewall passivation, transparent current-spreading layers, and reflector structures to support high-speed modulation and efficient coupling to integrated waveguides.

In some embodiments, the multiple-quantum-well portion of the active region 120 may be implemented with a limited well count to reduce carrier transit time and parasitic capacitance. For example, a stack with up to five wells may be selected to support high-speed modulation at small lateral pixel dimensions. A cap disposed above an uppermost well may be selected to establish a controlled spacing to the electron blocking layer 125, which may limit electron leakage while maintaining a low-resistance path for drive currents. Barrier thickness and composition may be coordinated with the cap thickness to shape carrier capture and to moderate internal fields near the electron blocking layer 125.

In some embodiments, post-growth stabilization may be applied to the active region 120 to preserve interface abruptness and intended composition profiles. A thermal step compatible with surrounding III-nitride layers may be used to dehydrogenate and to relax growth-related surface states while limiting indium interdiffusion within the wells. The thermal budget may be selected in view of the cap and barrier compositions so that confinement characteristics of the wells remain within desired windows for modulation response.

In some embodiments, wafer-scale uniformity of the active region 120 may be promoted using in-situ monitoring during epitaxy and closed-loop recipe control to maintain well thickness, barrier thickness, and indium composition across a wafer. Monitoring signals obtained during deposition may be used to adjust precursor delivery or temperature to compensate for spatial or temporal drift, and post-growth mapping may be used to verify uniformity across die intended for chiplet assemblies. Process windows may be selected to maintain consistent emission characteristics after subsequent pixel definition and contact formation.

In some embodiments, carrier-management structures may be coordinated with the electron blocking layer 125 to condition band alignment at boundaries of the active region 120. On the n-side, cladding or field-shaping layers disposed adjacent to the n-type gallium nitride layer 115 may be selected to set conduction-band profiles that promote electron injection while limiting leakage paths. On the p-side, spacing and composition adjacent to the electron blocking layer 125 may be selected to reduce charge accumulation and to set valence-band profiles compatible with rapid hole injection under high-frequency drive. Doping distributions within the cladding regions may be selected to support these band profiles without increasing series resistance.

In some embodiments, the active region 120 may be configured to cooperate with pixel geometries, sidewall passivation, transparent current-spreading layers, and reflector structures so that devices patterned to small lateral dimensions exhibit high-speed modulation with stable optical output. The confinement profile provided by the wells and any superlattice layering may be selected to maintain radiative recombination under current steering and direct current modulation, and the spacing to overlying layers may be selected to preserve the intended capacitance and resistance characteristics during subsequent processing.

In some embodiments, the design characteristics of the active region 120 may be selected to support high switching speeds by increasing radiative recombination rates and limiting charge transport delays. Thin quantum wells with well thickness at or below 3 nanometers may increase electron-hole wavefunction overlap and shorten recombination lifetimes, and a quantum-dot superlattice may provide three-dimensional confinement that further concentrates carriers within radiative states. These confinement choices may cooperate with the electron blocking layer 125 and adjacent cladding to support optical transitions at frequencies suitable for high-bandwidth interconnect operation.

In some embodiments, spacing between the active region 120 and the electron blocking layer 125 may be maintained within a sub-100-nanometer distance. Reducing this separation may decrease diffusive capacitance and effective series resistance in the vicinity of the uppermost active sub-period, which may shorten carrier transit paths and support higher modulation bandwidth. The spacing may be set using a cap or barrier thickness that preserves the intended confinement profile while maintaining a low-impedance path for drive currents. In some embodiments, spacing between an uppermost active sub-period of the active region 120 and the electron blocking layer 125 may be about 10 to 100 nanometers. The spacing may be implemented using a cap or barrier thickness selected to reduce diffusive capacitance and series resistance while maintaining the intended confinement profile

In some embodiments, the electron blocking layer 125 may be disposed above the active region 120 to present a conduction-band barrier that limits electron spill-over toward the p-type gallium nitride layer 130 while maintaining a low-impedance path for hole injection. The electron blocking layer 125 may comprise an aluminum-containing III-nitride such as AlGaN, InAlGaN, or a digital-alloy superlattice implemented as short-period GaN/AlGaN stacks, with aluminum mole fraction selected to set the conduction-band offset relative to the wells of the active region 120. The electron blocking layer 125 may be p-type doped, for example with magnesium, to reduce series resistance and to promote hole transport across the junction and may be formed with a thickness selected to provide blocking efficacy while limiting added voltage drop during high-frequency modulation. In some embodiments, the electron blocking layer 125 may comprise an aluminum-containing III-nitride having a thickness of about 10 to 100 nanometers and an aluminum mole fraction of about 0.05 to 0.35. The electron blocking layer 125 may include a composition-graded portion adjacent to the active region 120 to temper polarization-related band tilts.

In some embodiments, the electron blocking layer 125 may be uniform in composition or composition-graded to temper polarization-induced band tilts at the interface to the active region 120. A graded Al profile may be used on the side facing the p-type gallium nitride layer 130 to improve hole injection, and a thin interfacial cap or setback layer may be disposed between the uppermost well and the electron blocking layer 125 to preserve the intended confinement profile and to mitigate interface roughness. The electron blocking layer 125 may be configured within a sub-hundred-nanometer thickness window, and one or more ultra-thin interlayers having increased aluminum content may be included locally to raise the effective barrier without materially increasing total thickness.

In some embodiments, the electron blocking layer 125 may be grown by metal-organic chemical vapor deposition or molecular beam epitaxy using process conditions selected to maintain abrupt interfaces with the active region 120 and the p-type gallium nitride layer 130. Growth sequences may include temperature or precursor-flow modulations to control aluminum incorporation and surface morphology, and subsequent thermal treatments compatible with surrounding layers may be applied to activate acceptors and to stabilize the band profile. The electron blocking layer 125 may be coordinated with doping and thickness selections in adjacent cladding so that band alignment supports efficient carrier capture in the active region 120 and reduced leakage at drive levels associated with small-pixel, high-speed operation.

In some embodiments, the p-type gallium nitride layer 130 may be disposed above the electron blocking layer 125 and may function as a hole-injection region and upper optical cladding for the active region 120. The p-type gallium nitride layer 130 may comprise magnesium as an acceptor species with a doping distribution selected to provide sheet resistance compatible with small-area pixels while limiting absorption near the emission band. The p-type gallium nitride layer 130 may be formed with a thickness in a sub-micrometer range and may include grading or localized p⁺ regions to shape band edges and contact behavior. Formation conditions may be selected to limit hydrogen passivation and compensation, and a post-growth activation anneal may be applied under a nitrogen-or inert-containing ambient to increase the fraction of active acceptors. Surface morphology and background impurity levels may be controlled to provide a clean, low-defect interface to overlying contact structures used later in pixel processing.

In some embodiments, the p-type gallium nitride layer 130 may have a thickness of about 50 to 400 nanometers, including subranges such as about 100 to 200 nanometers. A p⁺ contact cap disposed on the p-type gallium nitride layer 130 may have a thickness of about 5 to 50 nanometers and may be configured to facilitate low-resistance contact formation or integration with a transparent current-spreading layer. A highly doped p-type gallium nitride contact cap may be disposed on the p-type gallium nitride layer 130 to reduce specific contact resistance and to promote stable electrical interfacing with transparent current-spreading layers and reflective metal stacks used at the pixel level. The cap and underlying p-type gallium nitride layer 130 may be configured to improve injection uniformity by moderating potential barriers at the interface to the electron blocking layer 125.

In some embodiments, the p-type gallium nitride layer 130 may be integrated with a top-contact architecture selected for high-speed modulation. A p⁺ contact cap of gallium nitride or a very thin indium-containing nitride may be disposed on the p-type gallium nitride layer 130 to facilitate ohmic metallization or deposition of a transparent conductive layer used for current spreading at the pixel level. As an alternative architecture, a tunnel-junction stack may be formed above the p-type gallium nitride layer 130 to provide a low-resistance contact path while maintaining optical transmission toward extraction features. The interface between the p-type gallium nitride layer 130 and the electron blocking layer 125 may include a controlled setback or cap thickness to moderate polarization-related fields and carrier accumulation, and wafer-scale uniformity of thickness and activation may be selected to support consistent modulation response across die intended for chiplet assemblies.

In some embodiments, incorporation of magnesium in the p-type gallium nitride layer 130 may be controlled together with hydrogen removal and post-growth activation anneals to reduce compensation and non-radiative recombination pathways. Growth and thermal conditions may be selected to balance activation and surface stability so that operating voltage is reduced while maintaining the intended band alignment to the active region 120 and the electron blocking layer 125. These selections may cooperate with the confinement choices in the active region 120 to support GHz-range switching characteristics in micro-scale pixels intended for optical interconnect applications.

In some embodiments, doping distributions in the n-type gallium nitride layer 115 and the p-type gallium nitride layer 130 may be selected to reduce injection barriers and series resistance. Higher donor concentration in the n-type gallium nitride layer 115 may improve electron supply and lateral spreading, and higher acceptor concentration in the p-type gallium nitride layer 130 may support efficient hole injection into the active region 120. These selections may be coordinated with contact architectures to promote uniform current injection across small lateral pixel dimensions.

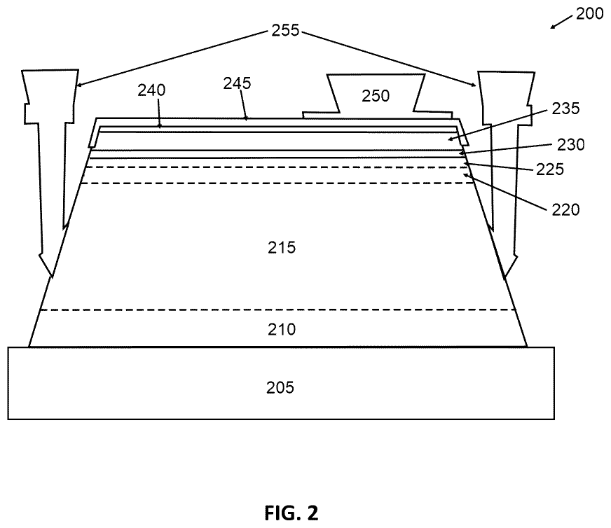

FIG. 2 illustrates an example pixel structure for a micro-light-emitting diode. The example single-pixel micro-light-emitting diode is depicted as a schematic cross-section in which relative layer thicknesses are not representative of actual dimensions. In some embodiments, the pixel 200 may be formed on a substrate 205 and may include a stack of III-nitride layers that cooperate with overlying optical and electrical features to provide emission when biased. In some embodiments, a first passivation layer 210 may be disposed on or adjacent to the substrate 205 around a pixel footprint and may provide electrical isolation, environmental protection, and local planarization. The first passivation layer 210 may be patterned so that sidewalls created during mesa definition are covered prior to formation of conductors, and so that routing metals may traverse adjacent regions without contacting exposed semiconductor.

In some embodiments, an n-type gallium nitride layer 215 may underlie an active region 220 that may include multiple quantum wells, and a quantum-dot, quantum-well layer 225 is shown in FIG. 2 to indicate an active-region variant that may be used in combination with, in place of, or omitted relative to the active region 220. An electron blocking layer 230 may be disposed above the active region and a p-type gallium nitride layer 235 may be disposed above the electron blocking layer 230 to provide hole injection and upper optical cladding.

In some embodiments, a transparent conductive current-spreading layer 240 may be disposed over the p-type gallium nitride layer 235 to promote uniform current injection with limited optical absorption, and a reflector 245 may be disposed over the transparent conductive current-spreading layer 240 to redirect emission toward an intended extraction or coupling path. A p-contact pad 250 may be formed over the reflector 245 and may be patterned for partial coverage of the pixel as depicted, and in some embodiments the p-contact pad 250 may be extended for full coverage to meet routing or process considerations. In some embodiments, one or more n-contact pads 255 may be arranged laterally with respect to the pixel and may be electrically coupled to the n-type gallium nitride layer 215 through etched windows or vias that expose an n-type region. The n-contact pads 255 may at least partly surround the pixel footprint to provide a low-resistance return path compatible with array pitch and interconnect routing.

In some embodiments, a reflector 245 may be formed over the transparent conductive current-spreading layer 240 to redirect emission toward an intended extraction or coupling path. The reflector 245 may comprise a metallic mirror such as aluminum-or silver-based films or may comprise a distributed Bragg reflector stack formed of alternating high-and low-index dielectric layers at device level. An adhesion and barrier sub-stack may be interposed between the reflector 245 and the transparent conductive current-spreading layer 240 to promote film integrity and to limit interdiffusion or oxidation, and a protective cap may be included to preserve reflectivity during subsequent processing. The reflector 245 may be patterned for partial coverage to balance optical throughput and contact routing or may extend across the pixel region to simplify metallization while maintaining the optical performance required by the selected stack.

In some embodiments, a p-contact pad 250 may be disposed over the reflector 245 and electrically coupled to the transparent conductive current-spreading layer 240 to provide a low-resistance connection to the p-type gallium nitride layer 235. The p-contact pad 250 may be patterned for partial coverage of the pixel aperture to reduce optical shading while maintaining a low series resistance, and in some embodiments the p-contact pad 250 may extend across the reflector 245 for full coverage to simplify routing or to satisfy process constraints. An adhesion and barrier sub-stack may be interposed between the p-contact pad 250 and the reflector 245 to promote film integrity and to limit interdiffusion, and one or more vias through the reflector 245 may be patterned to land directly on the transparent conductive current-spreading layer 240 where reduced drop is desired. The p-contact pad 250 may be routed to overlying interconnects or redistribution structures with geometry selected to manage parasitic capacitance and inductance at high modulation frequencies.

In some embodiments, the p-contact pad 250 may comprise a metal system selected to cooperate with the transparent conductive current-spreading layer 240, including stacks comprising titanium, chromium, nickel, palladium, platinum, copper, aluminum, silver, or gold, in combinations selected for adhesion, diffusion control, and reflectivity. A post-deposition thermal step may be applied to stabilize contact resistivity and stack interfaces. In some embodiments, a tunnel-junction top contact formed during epitaxy may be used so that the p-contact pad 250 is electrically coupled through a highly doped junction while preserving optical transmission through the device-level reflector 245. In some embodiments, a semi-transparent electrode over the p-type gallium nitride layer 235 may be used in place of the transparent conductive current-spreading layer 240, with a fine metal grid patterned to reduce series resistance while maintaining optical throughput.

In some embodiments, one or more n-contact pads 255 may be disposed laterally with respect to the pixel mesa and electrically coupled to the n-type gallium nitride layer 215 through etched windows or vias opened in the first passivation layer 210 and any overlying dielectrics. The n-contact pads 255 may be arranged as discrete lands or as a ring that at least partly surrounds the pixel to support lateral current return and to reduce current crowding at the mesa perimeter. The contact window to the n-type gallium nitride layer 215 may expose a locally higher conductivity region where an ohmic interface is formed, and the lateral routing of the n-contact pads 255 may be selected to maintain clearance to neighboring pixels at the intended array pitch. In some embodiments, the n-contact pads 255 may comprise metal stacks compatible with ohmic formation to n-type gallium nitride, and a thermal step may be applied to condition the interface. The geometry and thickness of the n-contact pads 255 may be selected to provide a low-inductance path for high-speed operation and to support electrostatic discharge robustness. The openings through the first passivation layer 210 for the n-contact pads 255 may be aligned to minimize step coverage challenges and to preserve passivation continuity around the mesa sidewalls. Where routing density is high, a planarization dielectric over the first passivation layer 210 may be used so that the p-contact pad 250 and the n-contact pads 255 are presented with comparable topography for subsequent interconnect metallization.

In some embodiments, the p-contact pad 250 and the n-contact pads 255 may be co-designed with the transparent conductive current-spreading layer 240 and the reflector 245 so that contact placement, via count, and metal cross-section cooperate to provide uniform current injection, controlled series resistance, and stable optical output. Guard-ring segments coupled to the n-type gallium nitride layer 215 may be included where additional lateral current return or edge-field moderation is desired. The contact metallurgy and passivation openings may be configured to maintain environmental robustness and long-term stability under the thermal and electrical conditions associated with small-pixel, high-frequency operation.

In some embodiments, the micro-light-emitting diode structure may incorporate a pixel design in which pixel geometry, contact configuration, and passivation techniques are adjusted to support external quantum efficiency, carrier recombination rates, and optical coupling into waveguides or fibers. The pixel size may be less than 15 micrometers to reduce carrier diffusion lengths and increase radiative recombination rates, and in some embodiments the pixel size may be greater than 5 micrometers. A p-contact pad 250 may be configured to contact a portion of an upper layer of the pixel to balance current spreading with optical shading. As lateral pixel size decreases, the surface-to-volume ratio may increase, which may promote faster recombination and improved modulation bandwidth. Pixel shaping may include conical or parabolic profiles that may collimate emission, improve directionality, and enhance coupling efficiency into guided modes, thereby optimizing photon extraction paths for wafer-scale optical interconnects. Pixelation may be implemented by a top-down lithography flow followed by wet etching or by reactive ion etching, and in some embodiments pixels may be produced by a bottoms-up approach in which a lithographically patterned hard mask on GaN seed layers defines regions for growth. A subsequent metal-organic chemical vapor deposition or molecular beam epitaxy step may grow GaN micro-rods or nano-rods that include a p-n junction, multiple-quantum-well active region, and electron blocking characteristics as described for the epitaxial design. In some embodiments, the hard mask may be removed after growth and pixelation and metallization may proceed.

In some embodiments, the n-type gallium nitride layer 215 may correspond to the n-type gallium nitride layer 115 with a donor species selected from silicon or germanium and a thickness selected to provide lateral current spreading at the pixel scale. The n-type gallium nitride layer 215 may further include local cladding or field-shaping sublayers that were formed during epitaxy and that remain beneath the pixel mesa after patterning. Access to the n-type gallium nitride layer 215 may be provided by windows or vias aligned to n-contact pads 255, and in some embodiments a locally heavier-doped n⁺ cap may be present to facilitate ohmic contact formation without changing the underlying epitaxial composition profile.

In some embodiments, the active region 220 may preserve the multiple-quantum-well structure, including well and barrier thickness selections, well counts, and indium content ranges as described for the epitaxial structure 100. The quantum-dot, quantum-well layer 225 shown in FIG. 2 may be implemented as a quantum-dot superlattice that complements the multiple-quantum-well stack, may replace the multiple-quantum-well stack, or may be omitted. Superlattice layering used to tune band offsets or strain in the epitaxial structure 100 may be carried forward into the pixel 200 so that confinement and polarization management remain consistent after mesa formation. Spacing between an uppermost active sub-period of the active region 220 and the electron blocking layer 230 may be maintained within a short distance selected to limit diffusive capacitance and series resistance while supporting high-frequency modulation.

In some embodiments, the electron blocking layer 230 and the p-type gallium nitride layer 235 may correspond to the electron blocking layer 125 and the p-type gallium nitride layer 130 described for the epitaxial structure 100. The electron blocking layer 230 may comprise an aluminum-containing III-nitride with uniform or graded composition, and the p-type gallium nitride layer 235 may comprise magnesium with an activation profile selected to provide hole injection and sheet resistance suitable for the pixel area. A p⁺ contact cap formed during epitaxy may remain above the p-type gallium nitride layer 235 to support integration with the transparent conductive current-spreading layer 240 and the reflector 245, and the cap thickness may be selected to preserve band alignment to the electron blocking layer 230 at the pixel boundary.

In some embodiments, an epitaxial distributed Bragg reflector positioned relative to the active region 220 as described for the epitaxial structure 100 may be present beneath and/or above the active region 220 within the pixel 200. When present, the distributed Bragg reflector may remain buried after mesa formation and may be covered by the first passivation layer 210 along exposed sidewalls. Alternatively, the pixel 200 may omit an epitaxial distributed Bragg reflector and instead employ a reflector 245 formed above the transparent conductive current-spreading layer 240. Both arrangements may be supported within the same process flow so that pixel geometry, passivation coverage, and contact routing remain compatible with array formation.

In some embodiments, the pixel 200 may be formed by patterning a hard mask on an epitaxial structure and etching to define a mesa through the p-type gallium nitride layer 235, across the electron blocking layer 230, and at least partially into the active region 220 above the n-type gallium nitride layer 215. The etch profile may be selected to yield tapered, conical, or parabolic sidewalls, and isolation trenches adjacent to the mesa may be formed during the same patterning sequence. The hard mask may be removed and a first passivation layer 210 may be deposited conformally over exposed sidewalls and surrounding regions. In some embodiments, the pixel 200 may be defined from the same epitaxial stack described for FIG. 1 so that the substrate 205, the n-type gallium nitride layer 215, the active region 220, the electron blocking layer 230, and the p-type gallium nitride layer 235 retain material selections, thickness windows, doping choices, and orientation options as previously described.

In some embodiments, access to the n-type gallium nitride layer 215 may be opened by selectively removing portions of the first passivation layer 210 and overlying films to form windows or vias for n-contact pads 255. A transparent conductive current-spreading layer 240 may be deposited over the mesa, a reflector 245 may be formed over the transparent conductive current-spreading layer 240, and a p-contact pad 250 may be patterned for partial or full coverage, after which the n-contact pads 255 may be completed to establish electrical coupling to the n-type gallium nitride layer 215.

In some embodiments, pixel formation may be achieved by selective-area growth of gallium nitride nano-rods or nano-wires on a previously formed III-nitride epitaxial layer. A lithography-defined hard mask may establish growth openings so that subsequent metal-organic chemical vapor deposition or molecular beam epitaxy produces vertically oriented structures that include an n-type base, an active region configured as multiple quantum wells and/or a quantum-dot superlattice, an electron blocking layer, and a p-type cap within each structure. The nano-structures may be embedded in a dielectric and planarized to expose a top surface suitable for forming a transparent conductive current-spreading layer 240, a reflector 245, and a p-contact pad 250, while windows or vias may be opened to the n-type region for n-contact pads 255. In some embodiments, the nano-rod or nano-wire approach may reduce threading dislocation density and increase three-dimensional carrier confinement relative to pixels defined solely by mesa etching, which may shorten recombination lifetimes, lower parasitic capacitance, and support GHz-range modulation at small lateral dimensions. Geometry of the nano-structures may be selected to present tapered or curved facets that aid emission collimation and coupling to integrated waveguides, and process windows may be chosen to maintain uniform height and emission characteristics across arrays intended for chiplet assemblies.

In some embodiments, the pixel design may incorporate several functional layers from the epitaxial design with modifications aligned to pixel architecture and integration. A reflector 245 may comprise a high-reflectivity metal such as silver or aluminum or a distributed Bragg reflector stack, and metal deposition may be conducted using tools and processes including sputtering, atomic layer deposition, electroless plating, electroplating, and evaporation. A distributed Bragg reflector stack may be hybrid bonded to a pixelated wafer or may be grown using semiconductor fabrication methods involving lithography, patterning, and material deposition. A p-Mg-rich p-type gallium nitride layer 235 described for the epitaxial design may be included in the pixel structure together with the electron blocking layer 230 positioned above the multiple-quantum-well active region 220. A quantum-dot, quantum-well layer 225 shown in the schematic may complement the multiple-quantum-well active region 220 or may replace it. An n-type gallium nitride layer 215 and n-contact pads 255 fundamental to the epitaxial stack may be integrated into the pixel. A passivation layer 210 composed of SiO₂, Al₂O₃, or another dielectric may be formed on the substrate 205 and around the pixel to provide isolation and planarity, and processes for forming oxide passivation may include chemical vapor deposition, thermal deposition, and related techniques.

In some embodiments, sidewall passivation and a first passivation layer 210 may be applied to cover exposed semiconductor at the mesa perimeter and surrounding field regions. The first passivation layer 210 may comprise a dielectric such as silicon dioxide or aluminum oxide and may be conformally deposited to reduce surface states, suppress non-radiative recombination, and provide electrical insulation between routing metals and exposed semiconductor. The first passivation layer 210 may be patterned to open contact windows or vias while maintaining continuous coverage across sidewalls to support device reliability and to enable planarization for overlying interconnects. The thickness and placement of the first passivation layer 210 may be selected to preserve the intended optical path and to avoid introducing parasitic capacitance that would limit high-speed operation.

In some embodiments, pixel sidewalls may be passivated with SiO₂ and/or Al₂O₃ to reduce surface defects and suppress non-radiative recombination, thereby supporting internal quantum efficiency and device longevity. The passivation layer 210 may act as an electrical insulator while preventing carrier loss at pixel edges. To support injection uniformity, the p-metal of the p-contact pad 250 may be patterned for partial coverage of the p-type gallium nitride layer 235 so that current spreading is promoted without excessive optical absorption, and in some embodiments full coverage may be used. An indium tin oxide transparent conductive current-spreading layer 240 may be disposed between the p-type gallium nitride layer 235 and the p-metal of the p-contact pad 250 to reduce localized resistive losses and improve carrier injection uniformity. The n-type gallium nitride metal contact coupled to the n-type gallium nitride layer 215 may be arranged as a ring-like structure that at least partly surrounds the active pixel area to enhance lateral current spreading and reduce resistive bottlenecks.

### Asymmetric Cavity SLEDS

In some embodiments, a light-emitting architecture may employ an asymmetric cavity to produce super-luminescent output suitable for short-reach guided-wave interconnects. A III-nitride epitaxial stack may include an active region configured for fast switching and a gain region optically coupled to that active region, together with a cavity structure having a lower-reflectivity output interface and a higher-reflectivity back reflector. Under forward bias within a selected non-lasing window, the device may emit amplified spontaneous radiation with increased spatial coherence relative to typical light-emitting diodes, which may favor injection of optical power into integrated waveguides at array density.

In some embodiments, the cavity geometry may be realized as a vertical structure formed along the growth axis or as a lateral structure defined adjacent to a pixel. Reflector implementations may include metal films, dielectric Bragg stacks, and diffraction gratings, singly or in hybrid combinations, with placement and effective reflectivity selected to promote partial feedback that shapes directionality and spectrum without favoring sustained oscillation. Cavity length may be set at micro-scale dimensions to balance gain, loss, and coupling so that operation remains within the intended non-lasing regime while presenting an emission profile suited to a butt-coupled facet, a grating transition, or a tapered mode converter.

In some embodiments, coupling to the photonic fabric may be established by aligning a lateral output interface to a planar waveguide entrance, by diffracting emission from a vertical pixel into a buried guide using a surface grating, or by using an adiabatic taper that adjusts effective index and field size near the interface. Coupler periods, fill factors, and depths may be selected to match design wavelength and polarization, and profiles may be apodized or chirped to widen alignment tolerance while limiting back-reflections toward the cavity. These interfaces may be co-designed with the multilayer waveguide stack so that bend loss, crossings, and vertical transitions remain within a link budget dominated by coupled-power efficiency.

In some embodiments, driver circuitry may provide forward-bias modulation while a control policy maintains operation within the non-lasing window across expected temperature and load variation. Initialization may determine a bias setpoint using telemetry such as monitor-tap power, spectral smoothness, or slope behavior, after which modulation depth may be chosen to meet eye-opening and error-rate objectives at a targeted energy-per-bit. Runtime adjustments may reference temperature estimates or receiver statistics so that coupled power remains near target without entering a lasing regime.

In some embodiments, this super-luminescent emitter class may be substituted for, or combined with, the micro-LED pixels already described while preserving the same chiplet, interposer, and multilayer-waveguide frameworks. Relative to typical micro-LEDs that present broad angular output and wide spectra, the asymmetric-cavity approach may yield a more concentrated emission pattern and smoother spectral characteristics that support stable coupling into small-NA guides, yet it may avoid laser threshold behavior and associated mode-management overhead in dense photonic fabrics.

In some embodiments, quantitative cavity targets may be specified to maintain amplified spontaneous emission while suppressing lasing. An output interface may exhibit an effective reflectivity less than about ten percent at the design wavelength and incidence, and a back reflector may exhibit an effective reflectivity greater than about ninety percent. Hybrid mirrors may be used to tune these values, for example by combining a dielectric Bragg stack with a thin metallic layer or by overlaying a surface-relief grating on a dielectric mirror to adjust polarization response and spectral bandwidth without increasing feedback at the output side.

In some embodiments, cavity length may be selected in a micro-scale range that positions operation within a non-lasing regime for the expected gain and loss. Representative lengths may be about eight to about nine micrometers measured along the principal feedback axis, with the selection accounting for group index, mirror phase, and process/temperature drift. Tolerance windows may be set so that the product of round-trip gain and effective reflectivity remains below unity across the intended operating envelope.

In some embodiments, facet and coupler conditioning may be applied to stabilize waveguide injection. Anti-reflection films may be deposited on the emitting facet, and one or more index-transition layers may be included between the emitter plane and a waveguide entrance. A controlled spacer gap may be maintained with spacers or an optically clear material of selected refractive index. Sidewall roughness and wall angle at a butt interface may be managed by optimized dry etch followed by a brief smoothing treatment, and planarization or polishing may be used to present a flat, square entrance plane to the waveguide core.

In some embodiments, manufacturing windows and metrology may be defined for optical structures that set feedback and coupling. Thickness and refractive index of dielectric mirrors may be tracked by in-situ reflectometry and verified by spectroscopic ellipsometry. Grating period and etched depth may be held within tolerance windows selected to maintain coupling efficiency and spectral smoothness. Cavity length may be controlled by lithographic placement and etch-depth calibration with ex-situ confirmation using profilometry, optical scatter measurements, or cross-section microscopy.

In some embodiments, a bias-control policy may be implemented to keep operation within a non-lasing window over temperature and device variation. Initialization may include a current sweep while monitoring a tap detector, coupled-power slope, or spectral smoothness to locate a bias setpoint below threshold. Guard-banding may be applied to current and temperature, duty-cycle and peak-to-average constraints may be enforced to avoid transient overshoot, and lookup tables indexed by temperature or supply may define modulation depth. Runtime feedback may adjust bias or swing to preserve target eye opening and coupled power. In some embodiments, sustained oscillation in comparable cavity geometries may occur at current-density levels on the order of about 2 kW/cm², and bias setpoints may be selected to remain below such regimes.

In some embodiments, representative mode-coupling factors into integrated waveguides may be used for system planning. A micro-light-emitting diode channel may couple on the order of about 0.05 of emitted power to the guided mode, a lateral super-luminescent cavity about 0.15, a vertical super-luminescent cavity about 0.20, and a vertical-cavity surface-emitting laser about 0.40. These values may inform lane count, link budget, and placement within a multilayer photonic fabric.

In some embodiments, an energy-per-bit methodology may separate static bias from dynamic swing. Measurements may be taken with a defined data pattern at a stated temperature and load. The static component may be computed from quiescent bias over the active duty cycle, and the dynamic component may be computed from incremental current and voltage during modulation while monitoring coupled optical power to confirm operation remains in the non-lasing regime. Reported pJ/bit may include data rate, extinction ratio, and coupling conditions.

In some embodiments, the photonic fabric may be specified to match emitter characteristics. Waveguides may be single-mode or multi-mode over the operating band with core materials such as silicon nitride, silicon oxynitride, aluminum nitride, or polymers selected for low loss. Multilayer routing may include vertical transitions between optical planes and managed crossings, with adiabatic mode transformers placed to control numerical aperture and field size at interfaces to emitters and detectors.

In some embodiments, a lateral cavity may be formed adjacent to a pixel by creating trenches or recesses that define mirror planes. Dielectric and/or metal fills may be deposited to realize high-reflectivity regions, followed by planarization to recover a flat surface. Lithographic registration may position a butt interface or grating input at a defined offset so that cavity length and coupling geometry remain within the intended tolerance window.

### Nanowire Implementation

In some embodiments, the pixel architecture described herein may be implemented using bottom-up III-nitride nano-rods or nano-wires in place of, or in combination with, mesa-defined pixels. The present draft already contemplates selective-area growth through a lithography-defined hard mask to form vertically oriented nano-structures that incorporate an n-type base, an active region configured as multiple quantum wells and/or a quantum-dot superlattice, an electron blocking layer, and a p-type cap, followed by dielectric embed and planarization compatible with subsequent transparent current spreading, reflector formation, and pad metallization. This flow may be mapped to the pixel stack and interconnects previously described so that array formation, passivation, and contact routing remain consistent with chiplet assembly.

In some embodiments, a GaN seed layer oriented on non-polar or semipolar planes (e.g., m-plane {10-10}, {10-11}, {11-22}) may be used beneath the nanowire array to reduce polarization fields within the active region and support shorter carrier lifetimes and high-speed modulation. Seed orientation, thickness, and crystalline quality may be verified by diffraction and microscopy, and selective-area epitaxy through patterned hard masks may set array pitch and placement. Vapor-liquid-solid initiation with metal nanoparticles may be used in conjunction with, or in place of, mask-mediated nucleation to tailor taper, axial composition, and facet formation.

In some embodiments, each nanowire may implement the junction axially or radially (core-shell), or in hybrid form. Axial implementations may sequence an n-type segment, an active region, and a p-type segment along the growth direction; radial implementations may employ an n-type core, a quantum-well or intrinsic shell, and a p-type outer shell, optionally including one or more blocking layers adjacent to the active region. Doping may use silicon or germanium donors and magnesium acceptors with uniform, stepped, or graded profiles and post-growth activation. In some embodiments, tunnel-junction stacks may be introduced to reduce contact resistance to the p-type side.

In some embodiments, array-level contacting may use conformal transparent conductors, wrap-around sidewall contacts, or planar top-caps in combination with redistribution layers, vias, and guard structures sized for GHz-class operation. Optical power from the array may be coupled into a photonic fabric by butt couplers, diffraction gratings, or evanescent side-couplers formed above, below, or alongside the emitter plane, with single-or multi-layer waveguide stacks of silicon nitride, polymers, or glass providing routing and fan-out to receivers. Alignment may be achieved by fiducials and adhesives compatible with index-matching and thermal management.

In some embodiments, the nanowire approach may be integrated into the same chiplet and interposer schemes described for planar pixels so that the CMOS driver/TIA, power delivery, and waveguide ports are preserved while substituting the emitter plane with a nanowire array chosen for reduced QCSE and improved recombination dynamics. Performance may reflect sub-nanosecond lifetimes and per-pixel bandwidths extending into the multi-GHz range, with lane aggregation used to achieve aggregate throughput targets at energy per bit compatible with the previously described system-level metrics.

In some embodiments, the same dielectric embed and planarization sequence already described for nano-rod/nano-wire pixels in the present draft may be applied to non-polar/semipolar arrays so that transparent current spreading, reflector deposition, p-and n-pad patterning, and subsequent packaging steps follow the established flow with adjustments to via placement and sheet resistance targets as needed for array pitch and coupling geometry.

In some embodiments, orientation of the GaN seed layer may be validated prior to nanowire growth using modality-specific metrology. Suitable procedures may include X-ray diffraction pole figures to confirm non-polar or semipolar planes, rocking-curve analysis to assess mosaic spread, electron backscatter diffraction mapping to verify in-plane grain orientation, atomic force microscopy to examine terrace morphology and step density, and transmission electron microscopy cross-sections to confirm crystallographic registry and interface quality.

In some embodiments, selective-area epitaxy may employ a hard mask chosen from silicon dioxide, silicon nitride, aluminum oxide, hafnium oxide, titanium oxide, amorphous silicon, or metals. Patterning may be performed by optical lithography, electron-beam lithography, nanoimprint, interference lithography, or spacer-defined techniques. Apertures may present circular, hexagonal, slot, or polygonal shapes with critical dimensions in a range from tens to hundreds of nanometers, arranged on square, rectangular, or hexagonal lattices that may be periodic, quasi-periodic, or aperiodic to balance density, coupling, and crosstalk.

In some embodiments, bottom-up growth windows may be defined for metal-organic chemical vapor deposition, molecular beam epitaxy, plasma-assisted MBE, or related chemical vapor deposition methods. Representative process ranges may include substrate temperatures of about 650-1100° C. at sub-Torr to atmospheric pressure for MOCVD and ultra-high-vacuum conditions with substrate temperatures of about 500-900° C. for MBE or plasma-assisted MBE. Vapor-liquid-solid initiation may be used with catalysts such as gold, nickel, or gallium, with catalyst presence, consumption, or removal selected to control taper, axial composition, and facet formation of the nanowires.

In some embodiments, post-growth treatments may include conformal passivation using aluminum oxide or silicon nitride deposited by atomic layer deposition or plasma-enhanced chemical vapor deposition. Dopant activation anneals may be applied according to the intended junction arrangement. In some embodiments, any residual catalyst may be removed, sequestered, or encapsulated. Encapsulation may include spin-on polymers, glass or ceramic caps, or hermetic sealing. In-line metrology may map photoluminescence, time-resolved photoluminescence, cathodoluminescence, and electrical proxies prior to device-level processing.

In some embodiments, the nanowire geometry may be selected to manage defects. Threading dislocations from the seed may bend out or terminate at nanowire sidewalls, and bottom-up formation may avoid etch-induced sidewall damage associated with mesa pixels. These effects may support improved internal quantum efficiency and uniformity at micrometer-scale pitches after dielectric embed and planarization.

In some embodiments, the active region of a nanowire may be implemented beyond simple axial wells. Annular or segmented quantum-well shells may be formed in a radial core-shell configuration and repeated or interleaved sequences may be arranged along the axis. Shell layers may also function as passivation and optical confinement. Electron or hole blocking layers may be placed proximate to the active region to shape carrier flow and reduce leakage.

In some embodiments, contact and interconnect variants may be used to support array operation. Transparent conductors may include indium tin oxide, indium zinc oxide, fluorine-doped tin oxide, patterned metal meshes, graphene, or conductive nanowire networks. Vertical interconnects may include through-dielectric vias or through-substrate vias that link to redistribution layers. Electrostatic-discharge paths, guard structures, and isolation features may be included to maintain stability at high switching speeds.

In some embodiments, optical interfaces to a photonic fabric may include evanescent side-couplers with controlled interaction length, butt interfaces aligned to waveguide inputs, or grating couplers positioned above or below the emitter plane. The photonic stack may include one or more layers of silicon nitride, polymers, or glass, with adiabatic tapers or mode transformers used to manage numerical aperture and transition loss. Absorbers and stray-light baffles may be placed to limit crosstalk and monitor taps may provide alignment and yield feedback during assembly.

In some embodiments, receiver structures may be co-packaged with the nanowire emitters. Photodiodes may include silicon, germanium, or indium gallium arsenide in p-i-n or avalanche configurations. Front-end electronics may include transimpedance amplifiers, limiting stages, and equalization circuits, and test access paths and calibration features may be provided for lane characterization and system bring-up.

In some embodiments, performance may be characterized by time-resolved optical measurements indicating carrier lifetimes on the order of hundreds of picoseconds to a few nanoseconds consistent with reduced polarization fields in non-polar and semipolar arrangements. Per-pixel electrical-optical bandwidth may extend from the hundreds of megahertz into the multi-gigahertz range at micrometer-scale pitches, with aggregate throughput set by lane count and coupling efficiency to the photonic fabric.

In some embodiments, nanowire arrays may be deployed beyond short-reach interconnects. Use cases may include illumination, compact projection, and sensing where high radiance and small emitter area are beneficial, and these functions may be integrated with the chiplet and interposer frameworks described herein.

### O/E Chiplets

In some embodiments, optical-electrical chiplets may integrate a micro-LED 310, a photodiode 315, and a silicon CMOS driver and transimpedance amplifier layer 305 on a common substrate to provide compact transmit/receive functionality for high-bandwidth links. In some embodiments, the chiplets may be attached to a waveguide-electrical interposer that includes low-loss dielectric waveguides and metal routing so that optical signals are coupled to guided modes while electrical signals are fanned out to package interconnects. Bonding may include hybrid bonding and flip-chip bonding with controlled planarity and spacing to maintain optical alignment. In some embodiments, copper bumps 325 and copper vias 330 may be used for power delivery, I/O, and high-speed signal paths. In some embodiments, alignment features, optically clear adhesive, and micro-lens elements proximate to the micro-LED 310 and/or the photodiode 315 may be used to increase coupling efficiency and tolerance to assembly variation.

In some embodiments, the chiplet architecture may be organized for bidirectional operation with the micro-LED 310 and the photodiode 315 disposed on opposite sides of a routing structure, such as a through-silicon bridge 320, or placed in stacked or laterally adjacent positions according to lane partitioning and pitch. The silicon CMOS driver and transimpedance amplifier layer 305 may provide serializer/deserializer interfaces, pre-emphasis or equalization, bias control, and monitoring circuits, and may be co-designed with copper vias 330 and copper bumps 325 to manage impedance, parasitic capacitance, and return paths at target data rates. Thermal paths through the chiplet and interposer may be selected to maintain junction temperature while preserving the optical alignment budget and reliability of bonded interfaces.

In some embodiments, the chiplet may be fabricated to be compatible with wafer-scale assembly flows so that multiple chiplets are placed onto a common waveguide-electrical interposer to realize dense arrays of links. The placement of the micro-LED 310 and the photodiode 315 relative to the silicon CMOS driver and transimpedance amplifier layer 305 may be selected to shorten electrical interconnect length, minimize timing skew, and preserve optical access to waveguide facets or grating couplers. The stack may accommodate variations that include device-level reflectors, transparent current-spreading films at the emitter, and guard or shielding conductors adjacent to the photodiode 315, while maintaining mechanical clearances and optical paths consistent with the intended integration scheme.

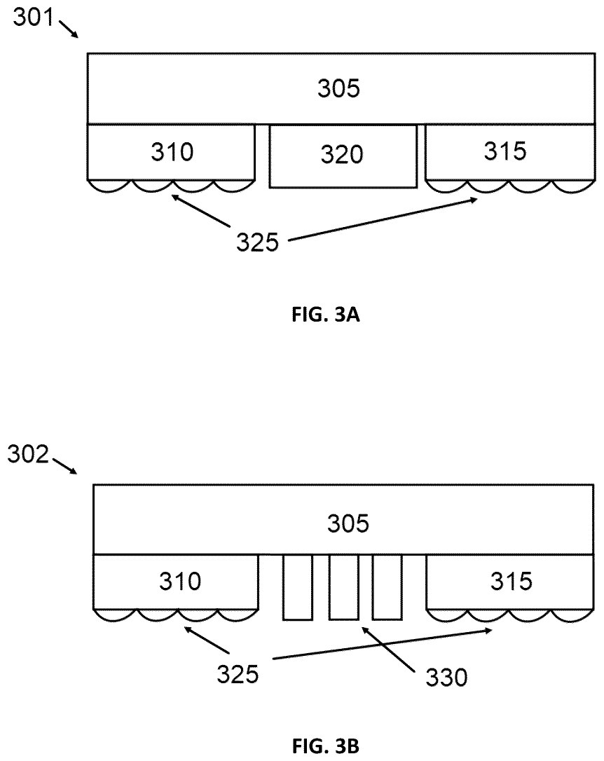

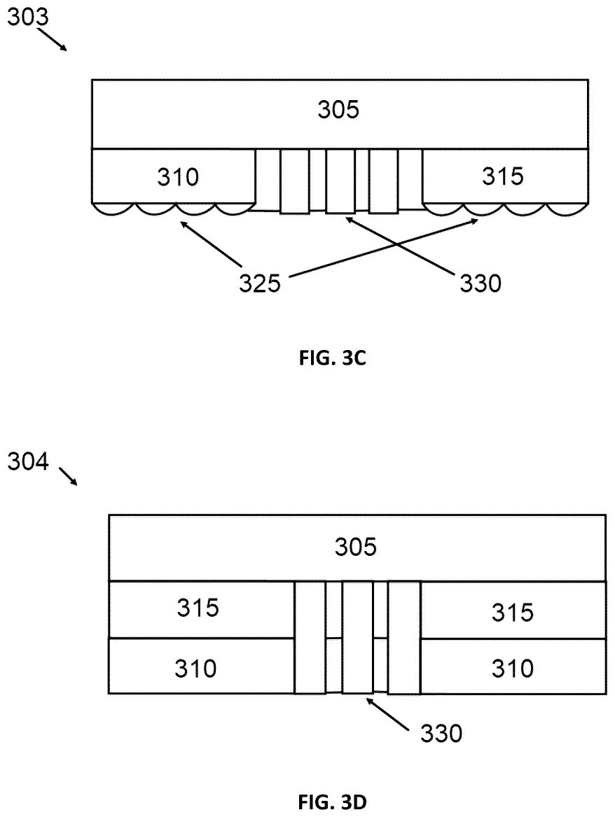

FIG. 3A depicts an example chiplet 301 configuration in which a silicon CMOS driver and transimpedance amplifier layer 305 is bonded to a through-silicon feature platform such as a through-silicon bridge 320 that provides fine-pitch redistribution between a micro-LED 310 and a photodiode 315. The chiplet 301 may be attached to a waveguide-electrical interposer that includes low-loss dielectric waveguides aligned to the micro-LED 310 and the photodiode 315 and metallization for power and I/O routing. Placement, planarity, and lateral registration may be selected to maintain optical alignment tolerance for coupling to the waveguide features of the interposer.

In some embodiments, the chiplet 301 may be realized by bonding the silicon CMOS driver and transimpedance amplifier layer 305 to a TSV-integrated chip that carries the through-silicon bridge 320, after which the assembly may be bonded to the waveguide-electrical interposer using hybrid bonding or flip-chip bonding. In some embodiments, copper bumps 325 may be formed on a bottom surface for mechanical attachment and electrical contact to the interposer. Thickness of the TSV-integrated chip and the stand-off established by the copper bumps 325 may be controlled to maintain an air gap less than 100 micrometers between optoelectronic surfaces and the interposer, and an optically clear adhesive may be used to set and stabilize the optical spacing during alignment. In some embodiments, optical coupling may be enhanced by micro-lens elements formed proximate to the micro-LED 310 and/or the photodiode 315 to collimate emission and increase capture into guided modes of the interposer waveguides. The bonding stack may include adhesion and barrier layers compatible with the copper bumps 325 and may be designed to manage impedance, return paths, and thermal conduction while preserving the optical alignment budget over temperature and time.

FIG. 3B depicts an example chiplet 302 structure that includes a silicon CMOS driver and transimpedance amplifier layer 305 disposed with a micro-LED 310 and a photodiode 315, where vertical interconnects are provided by copper vias 330 through dielectric regions and external attachment to a waveguide-electrical interposer is provided by copper bumps 325 and copper vias 330. The copper bumps 325 may be positioned at designated locations to register to interposer pads and waveguide ports, and bonding may be performed by flip-chip bonding or hybrid bonding with planarity and pitch selected for high-speed electrical routing and optical alignment.

In some embodiments, the height of the copper bumps 325 may be controlled to maintain an air gap less than 100 micrometers between an emitting or detecting surface and the interposer, with an optically clear adhesive used during placement to stabilize spacing and alignment. Micro-lens arrays may be integrated proximate to the micro-LED 310 and/or the photodiode 315 to collimate emission and increase capture into guided modes. The copper bumps 325 may comprise copper pillars with capping layers selected for adhesion and corrosion resistance, and an underfill or perimeter fillet may be used where mechanical reinforcement is desired without intruding into optical apertures. The copper vias 330 may be routed to provide low-inductance power and I/O paths between the silicon CMOS driver and transimpedance amplifier layer 305 and external connections while preserving return paths and minimizing parasitic capacitance at target data rates.

FIG. 3C depicts an example chiplet 303 structure in which copper vias 330 are embedded in silicon oxide between a micro-LED 310 and a photodiode 315 to provide vertical power and signal paths to a silicon CMOS driver and transimpedance amplifier layer 305. The copper vias 330 may be patterned and filled through an oxide stack to yield high-aspect-ratio conductors with surrounding dielectric that provides mechanical support and electrical insulation. Copper bumps 325 may be formed on a bottom surface of the chiplet 303 for attachment to a waveguide-electrical interposer, with bump placement registered to interposer pads and optical ports.

In some embodiments, bonding to the waveguide-electrical interposer may be performed by flip-chip or hybrid bonding, and the via height and bump stand-off may be controlled to maintain an air gap less than 100 micrometers between emitting or detecting surfaces and the interposer. An optically clear adhesive may be used during placement to stabilize spacing and lateral alignment. The copper vias 330 may comprise copper or copper-alloy conductors with barrier and seed layers selected for reliability, and the copper bumps 325 may comprise copper pillars with capping layers selected for adhesion and corrosion resistance. Routing through the copper vias 330 and across redistribution features in the silicon CMOS driver and transimpedance amplifier layer 305 may be arranged to manage impedance, return paths, and parasitic capacitance for high-speed operation. In some embodiments, micro-lens arrays may be positioned proximate to the micro-LED 310 and/or the photodiode 315 to collimate emission and increase capture into guided modes in the interposer waveguides. The dielectric surrounding the copper vias 330 may be patterned to maintain optical clearances and to preserve the alignment budget over thermal excursions while providing a stable mechanical path for the bonded assembly.

FIG. 3D depicts an example chiplet 304 structure that integrates multiple device layers hybrid bonded across substantially an entire die surface. A silicon CMOS driver and transimpedance amplifier layer 305 may be disposed above a photodiode layer 315 with a micro-LED layer 310 beneath, and in some embodiments the micro-LED layer 310 may be positioned above the photodiode layer 315. The stacked device layers may be partitioned into sub-arrays, including quadrant-style groupings, to support bidirectional operation, lane partitioning, redundancy, and independent bias control while preserving optical access to coupling features.

In some embodiments, copper vias 330 may be etched and filled through one or more of the stacked layers at locations designated for power delivery and input/output connectivity. The copper vias 330 may terminate at bond pads configured for flip-chip or hybrid bonding to a waveguide-electrical interposer, with an air gap between optoelectronic surfaces and the interposer controlled during assembly and filled with an optically clear adhesive to stabilize spacing and lateral registration. Micro-lens arrays may be formed proximate to the micro-LED layer 310 and/or the photodiode layer 315 to collimate emission and increase capture into guided modes within low-loss waveguides of the interposer, and routing through the copper vias 330 may be arranged to manage impedance, return paths, and thermal conduction consistent with target data rates and reliability.

### Waveguide Interposer with O/E Chiplets

In some embodiments, chiplet interconnect structures may couple a micro-light-emitting diode and a photodiode to a waveguide-electrical interposer so that optical and electrical paths are co-packaged for high-density, low-latency communication. The waveguide-electrical interposer may include low-loss dielectric waveguides with claddings selected for mode confinement and bend performance, together with metal routing for power and I/O distribution. The silicon CMOS driver and transimpedance amplifier layer may provide electrical interfaces and control functions for electrical-to-optical and optical-to-electrical conversion while managing biasing, equalization, and monitoring suitable for high-speed operation.

In some embodiments, optical transmit paths may originate at the micro-light-emitting diode, which may be modulated at GHz-range frequencies and aligned to an optical port of the waveguide-electrical interposer. Coupling elements may include edge couplers, grating couplers, tapered waveguide sections, or micro-lens features positioned to shape numerical aperture and increase coupling efficiency into guided modes. Receive paths may terminate at the photodiode, which may be positioned to capture guided light exiting a waveguide port or reflected by device-level optics, with the transimpedance amplifier in the silicon CMOS driver and transimpedance amplifier layer configured for low-noise current conversion and downstream signal conditioning.

In some embodiments, mechanical and electrical attachment to the waveguide-electrical interposer may be achieved by hybrid bonding and flip-chip bonding using copper bumps and copper vias arranged to maintain planarity, spacing, and alignment tolerances for optical ports while providing controlled impedance electrical paths. Alignment features and optically clear adhesives may be used to establish and stabilize the optical gap and stack materials may be selected to manage thermal expansion so that optical registration and electrical reliability are preserved over operating conditions. In some embodiments, interconnect density may be increased by using multi-layer waveguide stacks within the waveguide-electrical interposer so that optical links occupy multiple depths without increasing lateral footprint. Link capacity may be further managed by arranging multiple emitters and detectors per chiplet lane, by employing micro-lens arrays to collimate or focus emission, and by coordinating the placement of copper vias and local shielding conductors to limit electrical and optical crosstalk. The chiplet interconnect structures may be organized for bidirectional operation with routing selected to shorten electrical interconnect length to the silicon CMOS driver and transimpedance amplifier layer while maintaining clear optical paths to the integrated waveguides.

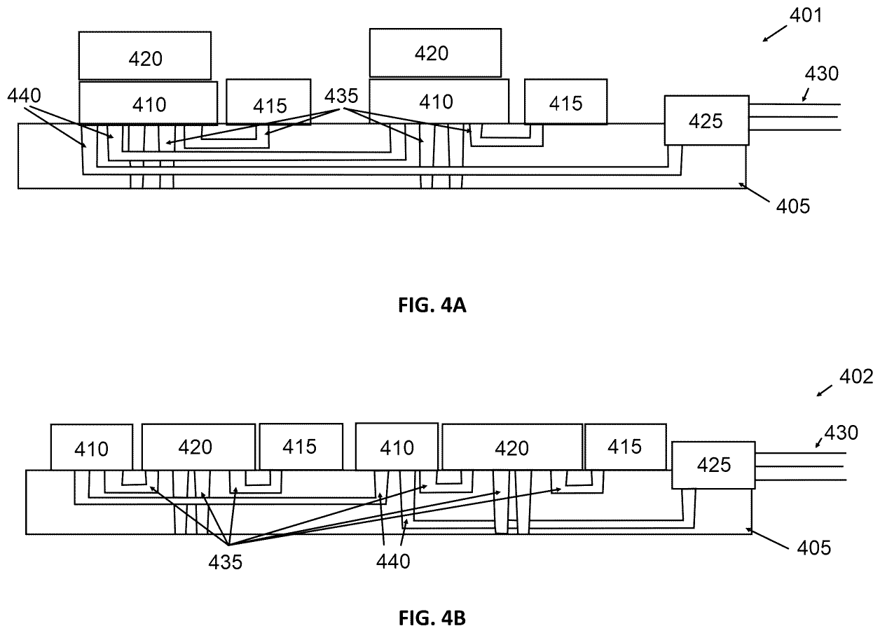

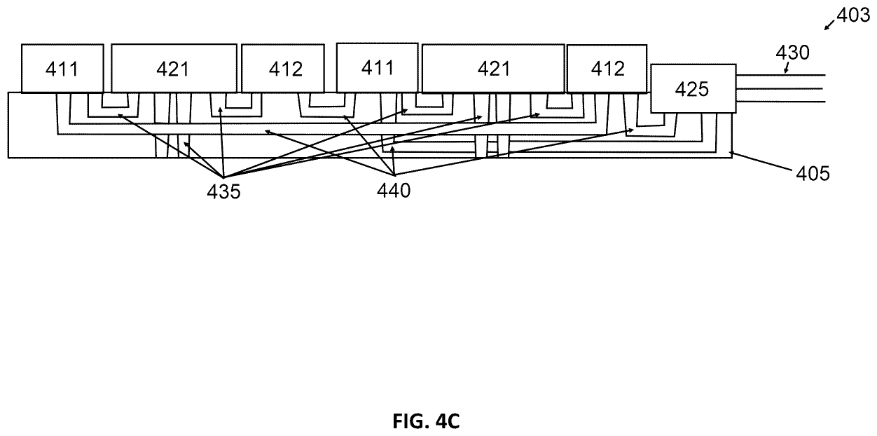

FIG. 4A depicts an example integration scheme 401 in which a waveguide-electrical interposer 405 supports two optical-electrical chiplets 410 that are laterally separated. A plug-in port 425 coupled to an optical fiber 430 may interface to a waveguide 440 of the waveguide-electrical interposer 405 and deliver an optical signal directly to a first optical-electrical chiplet 410. The first optical-electrical chiplet 410 may perform electrical-to-optical and optical-to-electrical conversion and may be optically coupled by a waveguide 440 to a second optical-electrical chiplet 410 to establish a hierarchical optical interconnect topology across the waveguide-electrical interposer 405.

In some embodiments, a graphics processing unit 420 may be disposed above each optical-electrical chiplet 410 to provide direct electrical communication between the graphics processing unit 420 and the underlying optical-electrical chiplet 410. A high-bandwidth memory module 415 may be positioned adjacent to each optical-electrical chiplet 410 and electrically coupled by connections 435 for low-latency data exchange and power distribution. Electrical connections 435 may further traverse the waveguide-electrical interposer 405 to provide inter-chiplet signaling, control, and shared power rails while maintaining clear optical pathways within the waveguides 440.

In some embodiments, the first optical-electrical chiplet 410 may interface directly with its associated high-bandwidth memory module 415 and may also communicate optically to the second optical-electrical chiplet 410 through the waveguide 440. The second optical-electrical chiplet 410 may be electrically coupled to a second high-bandwidth memory module 415 and may support a second graphics processing unit 420, enabling a scalable multi-graphics-processing-unit arrangement with distributed memory access. Placement, planarity, and spacing of the optical-electrical chiplets 410, the graphics processing units 420, and the high-bandwidth memory modules 415 on the waveguide-electrical interposer 405 may be selected to preserve optical alignment to the waveguides 440 and to manage electrical impedance and thermal paths for high-bandwidth operation.

FIG. 4B depicts an example integration scheme 402 in which the optical-electrical chiplets 410, graphics processing units 420, and high-bandwidth memory modules 415 are all mounted on the waveguide-electrical interposer 405. A plug-in port 425 coupled to an optical fiber 430 may feed a waveguide 440 that delivers an optical signal to a first chiplet 410, and a further waveguide 440 may route between chiplets 410 to establish on-interposer optical connectivity. Each chiplet 410 may perform electrical-to-optical and optical-to-electrical conversion while registering its optical ports to corresponding waveguide features of the interposer 405.

In some embodiments, each chiplet 410 may be electrically coupled to a proximate graphics processing unit 420 by connections 435 arranged on the interposer 405, and each graphics processing unit 420 may, in turn, be electrically coupled to a high-bandwidth memory module 415. The connections 435 may provide controlled-impedance paths for I/O and power distribution across the interposer 405 and may span between chiplets 410 and graphics processing units 420 to support lane aggregation, clock distribution, and management traffic. Lateral placement of the graphics processing units 420 adjacent to the chiplets 410 may reduce electrical interconnect length while preserving clear optical paths within the waveguides 440.

In some embodiments, planarity, spacing, and lateral registration on the waveguide-electrical interposer 405 may be selected to maintain optical alignment tolerance at the plug-in port 425 and at chiplet-to-waveguide interfaces while meeting electrical routing and thermal objectives. The interposer 405 may include multi-layer waveguide routing and metal layers so that optical links and electrical connections 435 scale in density without increasing lateral footprint, enabling expansion to additional chiplets 410 and associated graphics processing units 420 and high-bandwidth memory modules 415.

FIG. 4C depicts an example integration scheme 403 in which discrete optoelectronic and compute elements are placed on a waveguide-electrical interposer 405 rather than being combined into optical-electrical chiplets. A plug-in port 425 coupled to an optical fiber 430 may couple light into a waveguide 440 routed on the waveguide-electrical interposer 405 toward a photodiode 412. The photodiode 412 may convert received optical signals to electrical signals provided to a GPU-driver combination 421, which may, in turn, provide an electrical drive to a micro-light-emitting diode 411 for electrical-to-optical conversion. Electrical connections 435 on the waveguide-electrical interposer 405 may distribute power and I/O between the photodiode 412, the GPU-driver combination 421, and the micro-light-emitting diode 411 while preserving clear optical routing in the waveguides 440.

In some embodiments, the arrangement shown in FIG. 4C may be replicated as multiple sets on the waveguide-electrical interposer 405 so that at least two photodiode-GPU-driver-micro-light-emitting-diode signal chains operate in parallel. Waveguides 440 may route optical inputs from the plug-in port 425 to one or more photodiodes 412 and may route optical outputs from one or more micro-light-emitting diodes 411 toward the plug-in port 425 or toward other photonic nodes on the waveguide-electrical interposer 405. Electrical connections 435 may be organized to shorten paths between the photodiode 412 and the GPU-driver combination 421 and between the GPU-driver combination 421 and the micro-light-emitting diode 411, and placement may be selected to maintain alignment tolerances for coupling to the waveguides 440 and to manage thermal and impedance objectives for high-bandwidth operation.

In some embodiments, the arrangement of FIG. 4C may be repeated to form a cascaded optical-electrical interconnect in which a second photodiode 412 converts an optical signal received from a preceding node into an electrical signal provided to a second GPU-driver combination 421. The second GPU-driver combination 421 may then drive a second micro-light-emitting diode 411 to generate an optical output that may be routed back toward an upstream photodiode 412 or propagated further along waveguides 440 to additional nodes on the waveguide-electrical interposer 405.

In some embodiments, the GPU-driver combination 421 may be realized as a hybrid-bonded assembly in which a driver and a transimpedance amplifier are bonded to GPU silicon within the chip-level stack. In some embodiments, driver-TIA circuitry may be integrated into the GPU silicon so that the GPU-driver combination 421 is implemented monolithically during GPU design and tape-out. These integration options may support high-density links for AI acceleration and high-performance computing workloads by providing optical I/O paths that address energy-efficiency and bandwidth-scaling constraints associated with conventional electrical interconnects.

In some embodiments, a waveguide-electrical interposer 405 may be construed functionally as a substrate assembly that supports co-packaged optical routing and electrical distribution. The optical routing may be implemented as integrated waveguides 440 in dielectric stacks, as embedded or laminated fiber arrays within or upon the substrate, or as free-space optical paths defined by micro-lenses, prisms, or mirrors aligned between optical ports. The optical routing may also reside in a separate optical tile bonded above or below the electrical substrate, or within back-end metallization of a compute die, with optical coupling provided by edge couplers, vertical grating couplers, ferrule interfaces, or board-edge windows. Device placement may include stacked or lateral arrangements in which a graphics processing unit 420 is above an optical-electrical chiplet 410 or positioned adjacent to it, and optical ports such as the plug-in port 425 may be realized by any interface configured to mate an external optical conduit to the on-package optical routing.

In some embodiments, an optical-electrical chiplet 410 may include a light source and a detector selected from micro-LEDs 310, vertical-cavity surface-emitting lasers, edge-emitting lasers with on-package modulators, or integrated electro-optic modulators driven by an external laser, together with photodiodes 315 or avalanche photodiodes and receive-side amplification. Transmit/receive functions may be partitioned across multiple tiles or aggregated monolithically within a compute die, and link topology may include chiplet-to-chiplet paths on or across the package, chiplet-to-optical-hub tiles with wavelength-division fan-in/fan-out, and chiplet-to-edge interfaces that couple directly to off-module conduits, while maintaining electrical fan-out through the interposer 405.

In some embodiments, vertical and lateral interconnects may include copper vias 330, tungsten vias, through-glass or through-mold vias, plated studs, or anisotropic conductive structures, and external attachment may employ hybrid bonding, flip-chip bonding, thermocompression, or related techniques. Stand-off and optical spacing may be established by copper bumps 325, dielectric or polymer spacers, cured index-matched materials, or air gaps, with dimensions selected to meet optical coupling, impedance, and thermal targets without reliance on any specific numeric threshold. Materials for optical routing may include silicon nitride, silica, polymer, or glass, and reflectors, current-spreading layers, and contact stacks may be chosen from known equivalents while preserving optical access and high-speed electrical behavior across the package.

### Waveguide Network Design

In some embodiments, a waveguide network may provide passive optical interconnects so that optical signals are transmitted without integrated modulators within the waveguide stack while maintaining high bandwidth and low loss. The waveguide routing may support variable pitch and path length and may be implemented as one or more stacked layers that incorporate optical combiners and reflector mirrors to optimize path count, fan-out, and turn density. Electrical lines for power delivery and I/O may be co-routed in the same interposer substrate so that optical and electrical paths are presented in a coordinated stack. A fan-out structure may be included to interface a plug-in port to external optical conduits so that signals can be routed beyond a package-level interposer.

In some embodiments, waveguide pitch, layer count, and vertical spacing may be selected as a function of light-source pixel pitch and switching frequency. Higher-frequency sources may require fewer concurrent optical channels for a target aggregate bandwidth and therefore may allow a lower routing density, whereas lower-frequency sources may utilize a larger channel count and therefore may benefit from tighter pitch and additional layers. A hierarchical topology may be used in which upper layers carry longer-range trunks while lower layers provide dense local fan-in/fan-out proximate to emitters and detectors.

In some embodiments, the waveguide core may comprise off-the-shelf materials such as silicon nitride, silicon carbon nitride, aluminum oxide, or gallium nitride. Claddings may comprise thermal silicon dioxide, low-pressure chemical vapor deposition silicon dioxide, or atomic-layer-deposited aluminum oxide to provide index contrast, confinement, and low propagation loss. Waveguide pitch may range from sub-200 nanometers to several tens of micrometers depending on path count and bend constraints, with core dimensions selected for the operating band. For wavelengths in a range spanning approximately 400 to 900 nanometers, typical single-mode cores may be on the order of 300 to 500 nanometers in width and 200 to 300 nanometers in thickness.

In some embodiments, stacking may be used to relieve routing congestion for both optical and electrical paths. When pixel pitch tightens and electrical lines cannot be accommodated in a single metal/dielectric pair, additional metal-dielectric layers may be introduced to relax line-space requirements. A similar approach may be applied to optical routing, where waveguide layers are added to distribute channels vertically. Cladding dielectrics such as silicon oxide or aluminum oxide may also serve as optical claddings so that, for example, a one-micrometer-thick copper line adjacent to a one-micrometer-thick dielectric region may accommodate approximately three vertically spaced waveguides, each about 200 nanometers thick with about 200 nanometers of spacing between them, while preserving isolation to nearby conductors. In embodiments where waveguides are made thinner while still supporting the intended wavelength and reach, additional optical layers may be incorporated.

In some embodiments, fabrication may follow semiconductor process flows that include cladding deposition, lithography and patterning of trenches or channels, core-material deposition, and planarization. A representative sequence may deposit or plate a one-micrometer copper line over an underlying dielectric, form and fill waveguide cores such as silicon nitride adjacent to the copper termination and then deposit a cladding oxide to a partial thickness before pausing to define additional cores. Additional core-and-cladding steps may be repeated to realize a stacked structure. Layer placement may be directly stacked or vertically staggered to balance propagation length, bend radii, and crosstalk.

In some embodiments, the waveguide network may accommodate multiple light-source technologies. Micro-light-emitting diodes may provide directly modulated links at gigahertz-range frequencies. External lasers may be fiber-coupled into the network to support longer reach, higher modulation bandwidth, or power budgets set by system requirements. Vertical-cavity surface-emitting lasers may be integrated into opto-electrical modules with wavelength selections matched to waveguide dispersion. Quantum-dot light-emitting devices may be used where incoherent sources are preferred. Source selection may be made per lane or per tile to match link length and bandwidth density.

In some embodiments, couplers may be formed as tall, deep structures that project light directly into the core region to reduce reliance on tight-radius turns and to lower insertion loss. Edge couplers, etched mirrors, or grating couplers may be positioned to match numerical aperture at the emitter or detector interface. Bend strategy may favor gradual transitions, and total bend count along a routed path may be held to a low number to limit excess loss. Pixel pitch may be anisotropically adjusted so that one routing direction presents a wider pitch to accommodate electrical or optical traces while the orthogonal direction remains compact for array density.

In some embodiments, parallel optical transport over the waveguide network may proceed without serializer/deserializer circuitry in the communication path. Direct optical transmission between compute and memory elements may allow native parallel signaling over multiple lanes, which may avoid serialization, equalization, and clock-recovery overhead associated with long-reach electrical links. The approach may reduce power, lower end-to-end latency, and scale bandwidth by adding optical lanes and layers where board-level electrical signaling would otherwise constrain reach or density.

In some embodiments, routing strategy may be selected in view of light-source switching frequency. Links driven by higher-frequency sources such as vertical-cavity surface-emitting lasers in the tens-of-gigahertz range may achieve a target aggregate bandwidth with fewer pixels and therefore a lower optical lane count, while links driven by lower-frequency micro-light-emitting diodes on the order of a few gigahertz may employ a larger pixel count, tighter pitch, and increased waveguide layering. Stacking with at least two optical layers may be used as a baseline to accommodate growth in path count while preserving electrical routing clearances and bend margins for the intended wavelength band.

### System-level Architecture and Scalability

In some embodiments, dense optical-electrical chiplet integration may be implemented to provide an all-to-all communication interface across processing chips, memory modules, printed circuit assemblies, system-on-wafer architectures, panels, trays, racks, and cabinets. A multi-layer waveguide-electrical interposer may support parallel optical and electrical interconnects so that high-bandwidth, low-power links are established among heterogeneous compute resources. Aggregate data-movement capability may exceed about 10 Tbps/mm with energy per bit below about 3 pJ/bit, which may support scalable wafer-scale computing, AI acceleration, and high-performance computing workloads.

In some embodiments, per-channel operation may be selected to match reach and bandwidth targets. A micro-light-emitting-diode channel may switch at about 1 GHz and support transmission distances on the order of about 1 meter, and a vertical-cavity surface-emitting laser channel may switch at about 25 GHz and support distances up to about 30 meters. Multi-channel light sources may include uLEDs, VCSELs, quantum-dot LEDs, or combinations thereof. A single source type may be used where uniformity is desired, and multiple source types may be combined within a package to realize wavelength diversity and link optimization for mixed reach requirements.

In some embodiments, the waveguide-electrical interposer may convey optical signals over distances exceeding about 500 mm with low propagation loss, with a waveguide stack compatible with wavelengths in a range from about 400 nm to about 900 nm or beyond. Layer count and waveguide spacing may be determined as a function of pixel pitch using internal optimization methods to maintain transmission efficiency and manage cross-talk. Minimum waveguide pitch may range from sub-200 nanometers to several tens of micrometers depending on device scaling, optical routing complexity, and power-distribution constraints. Dedicated electrical lines may be incorporated for power delivery and I/O signal routing to and from optical-electrical chiplets.

In some embodiments, a waveguide-to-fiber coupling interface may be included so that optical signals are routed beyond a package-system interposer to additional modules, trays, and data-center infrastructure. The interface may maintain alignment to fiber plugs and may provide optical connectivity among cabinets, enabling distributed processing with low latency and coordinated bandwidth allocation across enclosures.

In some embodiments, the disclosed integration may be applied to AI training platforms, AI inference engines, mobile computing, automotive systems, and robotics. The ability to locate compute, memory, and photonic interconnects within a common multi-layer structure may provide high compute density and power efficiency suited to next-generation semiconductor packaging.

In some embodiments, a high-level architecture may include stacked waveguide layers that carry optical signals between compute and memory devices while electrical interconnects provide short-reach, low-latency coupling among adjacent modules. A repeating GPU-HBM arrangement may be used in which each GPU is electrically connected to a proximate HBM, and each HBM is electrically connected to another GPU so that side-by-side topologies support high-speed memory access. The waveguide layers may form parallel photonic paths among multiple GPUs and HBMs to relieve bandwidth limits associated with purely electrical links. The waveguide structure may be configured to reduce optical loss and cross-talk, and multi-layer stacking may accommodate increasing compute density without expanding lateral footprint. In some embodiments, HBM may be stacked above GPUs or vice versa (GPU above HBM) via hybrid bonding or flip chip bonding. The whole HBM-GPU stack may be further assembled onto the waveguide electrical interposer. An array of multiple such HBM-GPU ‘stacks’ may be connected to each other via an ‘all to all’ network supported using the abovementioned O/E chiplets and waveguide electrical interposers. O/E chiplets may contain uLEDs or VCSELs and the corresponding photodiodes.

In some embodiments, multiple system-level configurations may be used to scale deployment. A connected-tray configuration may include several trays integrated in a parallel optical-electrical network, each tray housing optical-electrical chiplets, GPUs, HBM modules, and interposer-integrated waveguide layers to support high-speed intra-tray and inter-tray communication. Optical waveguides may provide low-power transmission across a tray, and copper electrical interconnects may provide short-reach connectivity between adjacent processing and memory devices.

In some embodiments, a connected-cabinet configuration may include trays stacked within a rack. Inter-tray connectors may be positioned at the middle, top, bottom, or other locations to satisfy system-level optimization objectives, and cabinets may interconnect to adjacent cabinets to form a modular compute fabric with optical pathways spanning multiple enclosures. Resources may be allocated across trays while optical links maintain high-bandwidth, low-latency communication.

In some embodiments, a cabinet-in-a-box configuration may present a dense array of interconnected boxes within a compact enclosure that includes optical-electrical connected trays and integrated storage. Optical and electrical interconnects may span multiple levels to form layered data-transport paths. This arrangement may be advantageous for large-scale AI training, cloud data processing, and edge computing where power efficiency, latency, and throughput are co-optimized.

In some embodiments, a fiber plug-in interface may support system extension via fiber-optic cabling. Cable lengths on the order of about 1 to about 3 meters may be used, and longer distances may be supported according to constraints that include optical amplification and environmental conditions. This extension may link computing modules, sensors, and peripheral systems for robotics, automotive, industrial automation, distributed AI computing, and edge processing.

In some embodiments, uLED-based optical interconnects may support distances up to about 5 meters depending on waveguide optimization, fiber coupling, and signal-processing approaches, and VCSEL-based optical interconnects may support distances up to about 15 meters, with additional reach achievable based on system-level design. These link options may be used where low-latency, high-bandwidth, and energy-efficient communication is needed between separated computing units or between mobile and stationary components.

In some embodiments, fiber-based extensions may be deployed in robotic control systems to coordinate distributed processing nodes for real-time decision-making in autonomous robots and industrial automation. Automotive systems may employ the same interfaces to couple sensor arrays, central processors, and control subsystems; use cases may include AI-assisted navigation, vehicle-to-vehicle communication, and driver-assistance functions. High-performance edge environments may employ optical extension cables to link processing clusters with remote inference engines, data-acquisition units, or high-speed sensor networks. The scalability of the disclosed interconnects may support centralized and distributed computing models and may adapt to emerging requirements in high-speed computing, AI acceleration, and autonomous systems.

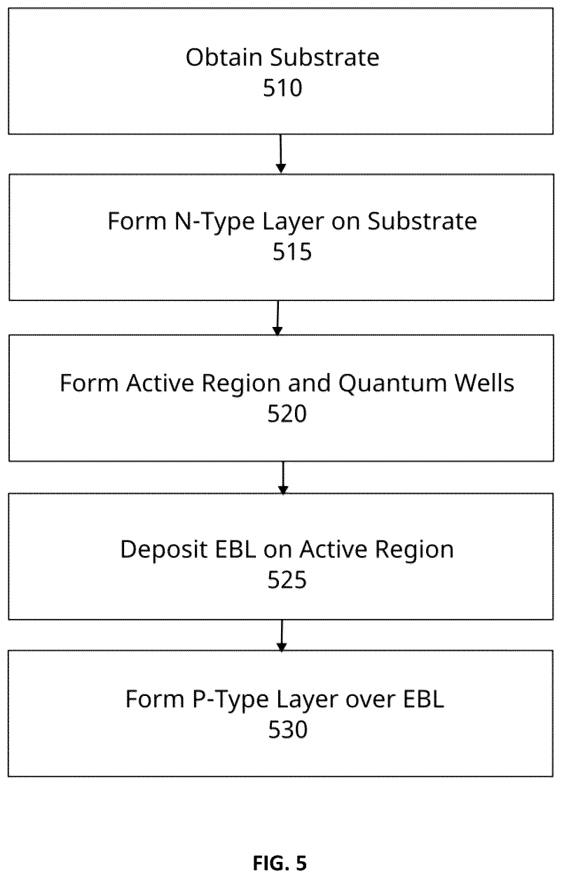

FIG. 5 depicts a method for fabricating a III-nitride epitaxial structure suitable for a micro-light-emitting diode. The blocks of the figure indicate a process sequence and the flow may be carried out using metal-organic chemical vapor deposition or molecular beam epitaxy with recipe selections targeting wafer-scale uniformity, low defect density, and interfaces prepared for subsequent pixel processing.

In some embodiments, step 510 may include obtaining a crystalline substrate selected from silicon, sapphire, silicon carbide, or gallium nitride with a surface orientation such as c-plane, m-plane, or semi-polar. The substrate may be prepared by miscut selection, surface clean, dehydration bake, and in-situ thermal conditioning to promote step-flow growth. The step may further include forming a nucleation film and a strain-management buffer on the substrate to accommodate lattice and thermal-expansion differences and to reduce threading dislocation propagation; the buffer may incorporate superlattice or graded-composition films to present a low-defect surface for subsequent layers.

In some embodiments, step 515 may include epitaxially forming an n-type gallium nitride layer doped with a donor selected from silicon and germanium to a thickness of about 0.5 to 5.0 micrometers. Some embodiments may include a thickness greater than 5.0 micrometers or less than 0.5 micrometers. The doping profile may be uniform for lateral current spreading or graded near the active-region interface to shape band alignment and polarization charge. Dislocation-reduction or cladding sublayers may be included within the n-type gallium nitride to improve crystalline quality, and a locally higher-dopant n⁺ region may be prepared at locations intended for ohmic contact formation. Surface morphology and background impurity levels may be controlled to provide an interface suitable for quantum-well formation.

In some embodiments, step 520 may include epitaxially forming an active region comprising a multiple-quantum-well stack of indium gallium nitride wells separated by barrier layers. Each well may have a thickness of 3 nanometers or less, and at least one well may include an indium mole fraction greater than 0.10 to increase electron-hole overlap and set the emission band. Barriers may comprise gallium nitride, aluminum gallium nitride, or indium gallium nitride with reduced indium content relative to the wells, with thickness selected to manage inter-well coupling. Interfaces may be sharpened by growth interrupts, pulsed precursor delivery, or migration-assisted steps, and superlattice layering may be introduced adjacent to one or more wells to tune band offsets and strain. A quantum-dot superlattice or a hybrid structure combining dot planes with thin wells may be used in place of, or in combination with, the multiple-quantum-well stack to provide three-dimensional confinement and spectral control. Spacing to a subsequent electron blocking layer may be kept short to limit diffusive capacitance while maintaining the intended confinement profile.

In some embodiments, step 525 may include forming an electron blocking layer adjacent to the active region with a thickness less than 100 nanometers. The electron blocking layer may comprise an aluminum-containing III-nitride such as AlGaN or InAlGaN and may be p-doped, for example with magnesium, to provide a low-impedance path for hole injection while presenting a conduction-band barrier that limits electron spill-over. Composition may be uniform or graded to temper polarization-related band tilts, and digital-alloy stacks may be used to realize an effective barrier with abrupt interfaces. A thin setback or cap between the uppermost well and the electron blocking layer may be included to preserve interface quality.

In some embodiments, step 530 may include epitaxially forming a p-type gallium nitride layer containing magnesium over the electron blocking layer. The thickness may be selected within a sub-micrometer range, including ranges such as about 100 to 200 nanometers for sheet-resistance targets compatible with micro-scale pixels. A post-growth activation anneal in a nitrogen-containing ambient may be applied to increase the fraction of active acceptors while limiting hydrogen passivation. A p⁺ contact cap of gallium nitride or a very thin indium-containing nitride may be grown on the p-type gallium nitride to facilitate subsequent contact stacks or transparent conductive films; in some embodiments a tunnel-junction stack may be prepared above the p-type gallium nitride to provide a low-resistance top-contact path while maintaining optical throughput.

In some embodiments, the method may include in-situ monitoring of optical or surface proxies to maintain well thickness, indium incorporation, barrier thickness, and electron blocking layer composition across the wafer. Recipe control may be used to compensate for spatial or temporal drift so that emission wavelength and modulation response remain uniform across die intended for chiplet assemblies. The resulting epitaxial structure may then proceed to pixel definition, sidewall passivation, transparent current-spreading layers, reflector formation, and contact metallization as described for the pixel embodiments.

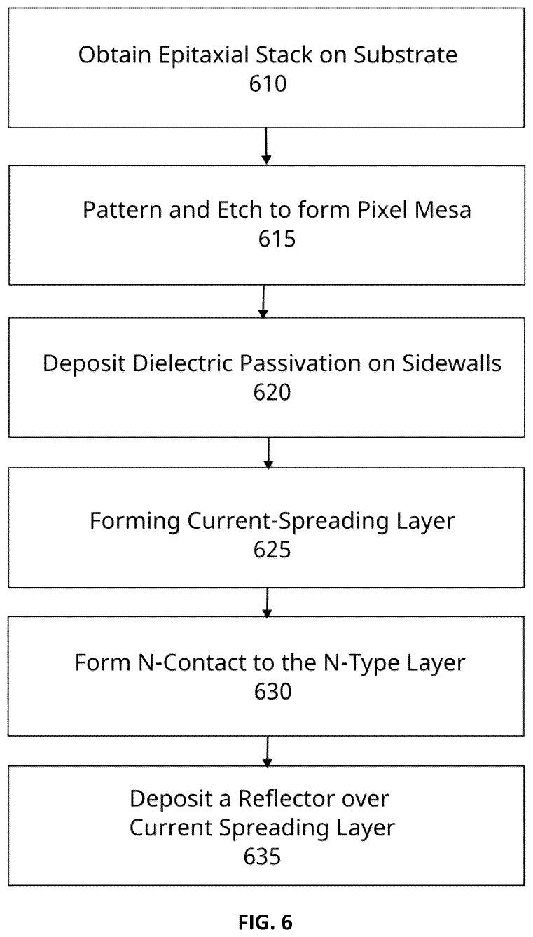

FIG. 6 depicts a schematic pixel-fabrication flow for a micro-light-emitting diode. The blocks indicate process sequence of an example method. The sequence may be executed with semiconductor tools compatible with wafer-level processing and with recipes selected to preserve epitaxial interfaces.

In some embodiments, step 610 may include obtaining a III-nitride epitaxial stack on a substrate, the stack including an n-type gallium nitride layer, an indium gallium nitride multiple-quantum-well active region, an electron blocking layer adjacent to the active region, and a p-type gallium nitride layer. The epitaxial stack may include cladding or field-shaping sublayers and may be provided with surface preparation compatible with mesa patterning.

In some embodiments, step 615 may include patterning and etching the epitaxial stack to form a pixel mesa having a lateral dimension less than 15 micrometers. The etch may proceed through the p-type gallium nitride layer and the electron blocking layer and at least partially into the active region above the n-type gallium nitride layer. Conditions may be selected to produce tapered, conical, or parabolic sidewalls that aid extraction and mitigate edge current crowding. Isolation trenches adjacent to the mesa may be defined in the same lithographic cycle to establish electrical isolation at the intended array pitch.

In some embodiments, step 620 may include depositing a conformal dielectric passivation on the mesa sidewalls. The passivation may comprise silicon dioxide, aluminum oxide, silicon nitride, or multilayer combinations deposited by atomic-layer deposition or plasma-enhanced chemical vapor deposition to suppress surface states and non-radiative recombination. The passivation may extend onto surrounding field regions to provide insulation and local planarization, and openings may be patterned later for contact windows and vias.

In some embodiments, step 625 may include forming a transparent conductive current-spreading layer over the pixel mesa and patterning the layer to define a p-contact region electrically coupled to the p-type gallium nitride layer. The transparent conductive current-spreading layer may comprise a transparent conducting oxide such as indium tin oxide, indium zinc oxide, or fluorine-doped tin oxide deposited by sputtering, pulsed-laser deposition, or atomic-layer deposition. Surface conditioning of the p-type gallium nitride layer may be performed prior to deposition to reduce contact resistance, and a thermal step may be applied to stabilize sheet resistance and transmittance.

In some embodiments, step 630 may include forming an n-contact to the n-type gallium nitride layer. Windows or vias may be opened through the dielectric passivation to expose an n-type region, and metal stacks compatible with ohmic formation to n-type gallium nitride may be deposited and patterned as pads that at least partly surround the mesa to provide a low-impedance return path. The routing geometry may be selected to meet array-pitch constraints and to maintain clearance to optical features.

In some embodiments, step 635 may include depositing a reflector over the transparent conductive current-spreading layer to redirect emission toward an intended extraction or coupling path. The reflector may comprise a metallic mirror such as aluminum-or silver-based films with adhesion/barrier sublayers, or a device-level distributed Bragg reflector stack formed of alternating high-and low-index dielectrics. Patterning may be used to preserve the defined p-contact region and to manage parasitic capacitance; protective caps or anti-tarnish layers may be included to maintain reflectivity during subsequent handling.

In some embodiments, array-scale integration may include planarizing topography around pixels using spin-on dielectrics or oxides followed by chemical-mechanical polishing so bonding surfaces present uniform height for hybrid or flip-chip attach. Redistribution metal may be formed over the planarized surface to route p-and n-nodes, with trace widths, spacings, and vias chosen to control impedance, limit parasitic capacitance, and provide low-inductance returns, and shields or guard rings tied to the n-node may suppress crosstalk. The emission plane may be registered to waveguide ports on an interposer using frontside and backside fiducials and coupling features such as edge or grating couplers or micro-lenses, while bond-line thickness and the optical gap may be set with spacers or index-matched materials and anti-reflection coatings or surface texturing may reduce Fresnel loss. Metal thickness, pillar placement, and under-bump metallization may be configured for heat spreading and mechanical stability so optical alignment, contact resistance, and modulation bandwidth remain within target windows at small lateral dimensions, and wafer-level test structures may validate optical power, bandwidth, and contact resistance prior to singulation.

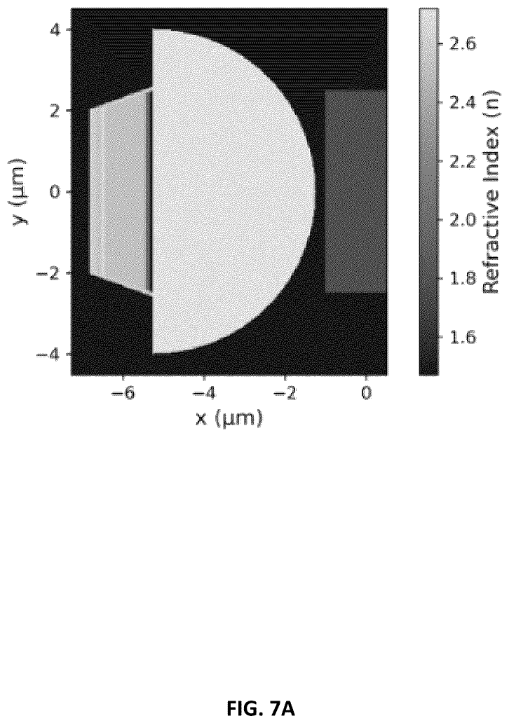

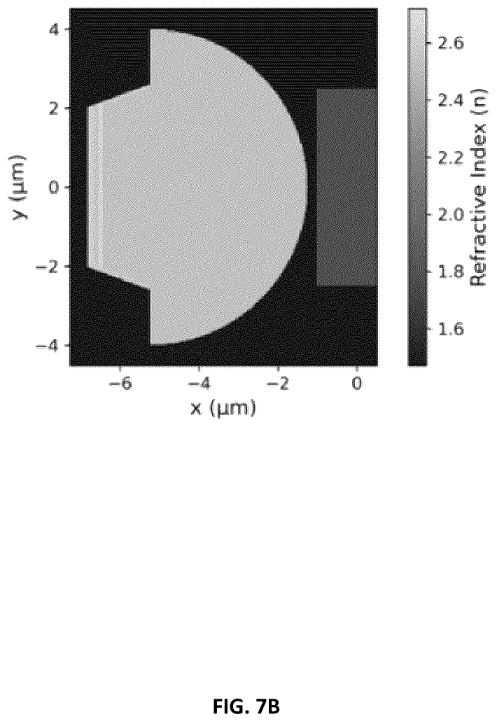

FIGS. 7A-7B illustrate example cross-sectional views of two different lens implementations associated with a GaN micro-light-emitting diode (micro-LED) pixel. In the illustrated examples, each figure depicts, in grayscale, a representative refractive-index distribution across the lens region and adjacent portions of the stack.

FIG. 7A illustrates a baseline lens implementation in which a lens element is formed from a material that is distinct from the GaN epitaxial stack of the micro-LED pixel. In some embodiments, the lens element comprises silicon carbide (SiC) or another off-the-shelf lens material. FIG. 7A further illustrates, via the grayscale refractive-index depiction, refractive-index transitions between the external lens element and neighboring regions.

FIG. 7B illustrates an embodiment in which the lens implementation comprises a monolithic GaN lens formed from GaN material of the micro-LED pixel itself (an “all GaN lens and stack” configuration). In some embodiments, the GaN lens is formed by shaping a portion of the GaN associated with the pixel (such as an n-type GaN region and/or one or more buffer layers) into a convex lens profile. The convex lens profile may be hemispherical, truncated-hemispherical, aspheric, or otherwise dome-shaped. FIG. 7B further illustrates, via the grayscale refractive-index depiction, a refractive-index distribution corresponding to GaN material in the lens region.

In some embodiments, the monolithic GaN lens of FIG. 7B is formed during wafer-level processing of the micro-LED pixel and, in some embodiments, is formed from GaN material that would otherwise remain as part of the pixel stack (e.g., an n-type GaN region and/or one or more buffer layers). The lens profile may be defined such that a curved GaN surface is produced over (or aligned to) an emission region of the pixel, with a target curvature selected to provide a desired optical effect (e.g., collimation, divergence control, or improved coupling to downstream optical elements).

By way of example, the monolithic GaN lens may be formed using one or more lithographic patterning and etch steps that transfer a rounded mask profile into GaN. In some embodiments, a reflowable resist (or other flowable material) is patterned to define an initial lens footprint and then reflowed to produce a domed topography, after which a dry etch and/or wet etch transfers the domed profile into GaN. In some embodiments, etch chemistry and etch selectivity are selected to control surface smoothness, sidewall slope, and lens sag height, and to reduce surface roughness that may otherwise increase scattering.

In some embodiments, the monolithic GaN lens may be formed using selective material removal and planarization techniques. For example, a planarization layer may be deposited and polished (e.g., via CMP) to expose a target portion of the GaN stack, after which controlled etching may be performed to create a convex GaN surface. In some embodiments, the lens surface is subsequently smoothed and/or passivated, and an optional anti-reflection coating or index-matching layer may be formed on the GaN lens surface.

In some embodiments, the monolithic GaN lens may be formed, at least in part, using selective-area regrowth to build a curved GaN surface. For example, openings may be defined in a mask layer, followed by epitaxial regrowth of GaN to form a dome-like profile, and subsequent shaping and/or planarization may be performed to achieve a target curvature. In some embodiments, regrowth-based formation is combined with etch-based shaping to improve surface profile control and uniformity across the wafer.

The GaN lens formation steps may be performed before or after pixel isolation, passivation, metallization, and/or planarization steps, and may be integrated with fabrication of micro-LED mesas, current-spreading layers, and/or contact structures. In some embodiments, the GaN lens is formed across an array of micro-LED pixels with a common process flow, and lens geometry may be uniform across the array or may vary between pixels (e.g., to account for different emission wavelengths, pixel positions, or coupling geometries).

In some embodiments, the lens is an example of an emission-collimation feature aligned to a mesa of the micro-LED pixel and may be used alone or in combination with other coupling structures (e.g., anti-reflection coatings, index-transition layers, gratings, tapers, or butt-coupling interfaces) to increase coupling of emitted light.

In a non-limiting simulation example comparing a baseline “SiC lens” configuration to an “all GaN lens and stack” configuration, the estimated coupling efficiency increased from approximately 6.8% (baseline) to approximately 9.4% (all GaN lens/stack). Accordingly, in some embodiments, forming the lens feature from GaN material of the pixel may provide improved coupling from a GaN micro-LED pixel into a waveguide relative to comparable configurations using an external lens material.

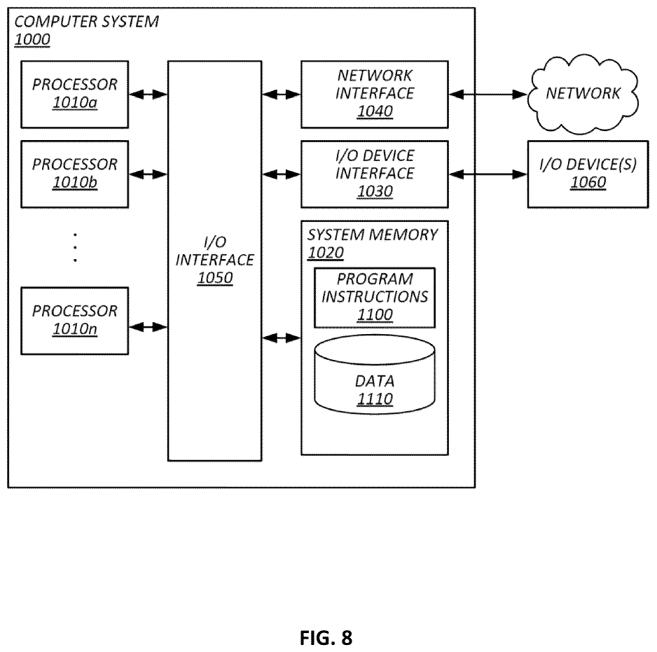

FIG. 8 is a diagram that illustrates an exemplary computing system 1000 in accordance with embodiments of the present technique. A single computing device is shown, but some embodiments of a computer system may include multiple computing devices that communicate over a network, for instance in the course of collectively executing various parts of a distributed application. Various portions of systems and methods described herein, may include or be executed on one or more computer systems similar to computing system 1000. Further, processes and modules described herein may be executed by one or more processing systems similar to that of computing system 1000.

Computing system 1000 may include one or more processors (e.g., processors 1010a-1010n) coupled to system memory 1020, an input/output I/O device interface 1030, and a network interface 1040 via an input/output (I/O) interface 1050. A processor may include a single processor or a plurality of processors (e.g., distributed processors). A processor may be any suitable processor capable of executing or otherwise performing instructions. A processor may include a central processing unit (CPU) that carries out program instructions to perform the arithmetical, logical, and input/output operations of computing system 1000. A processor may execute code (e.g., processor firmware, a protocol stack, a database management system, an operating system, or a combination thereof) that creates an execution environment for program instructions. A processor may include a programmable processor. A processor may include general or special purpose microprocessors. A processor may receive instructions and data from a memory (e.g., system memory 1020). Computing system 1000 may be a uni-processor system including one processor (e.g., processor 1010a), or a multi-processor system including any number of suitable processors (e.g., 1010a-1010n). Multiple processors may be employed to provide for parallel or sequential execution of one or more portions of the techniques described herein. Processes, such as logic flows, described herein may be performed by one or more programmable processors executing one or more computer programs to perform functions by operating on input data and generating corresponding output. Processes described herein may be performed by, and apparatus can also be implemented as, special purpose logic circuitry, e.g., an FPGA (field programmable gate array) or an ASIC (application specific integrated circuit). Computing system 1000 may include a plurality of computing devices (e.g., distributed computer systems) to implement various processing functions.

I/O device interface 1030 may provide an interface for connection of one or more I/O devices 1060 to computer system 1000. I/O devices may include devices that receive input (e.g., from a user) or output information (e.g., to a user). I/O devices 1060 may include, for example, graphical user interface presented on displays (e.g., a cathode ray tube (CRT) or liquid crystal display (LCD) monitor), pointing devices (e.g., a computer mouse or trackball), keyboards, keypads, touchpads, scanning devices, voice recognition devices, gesture recognition devices, printers, audio speakers, microphones, cameras, or the like. I/O devices 1060 may be connected to computer system 1000 through a wired or wireless connection. I/O devices 1060 may be connected to computer system 1000 from a remote location. I/O devices 1060 located on remote computer system, for example, may be connected to computer system 1000 via a network and network interface 1040.

Network interface 1040 may include a network adapter that provides for connection of computer system 1000 to a network. Network interface may 1040 may facilitate data exchange between computer system 1000 and other devices connected to the network. Network interface 1040 may support wired or wireless communication. The network may include an electronic communication network, such as the Internet, a local area network (LAN), a wide area network (WAN), a cellular communications network, or the like.

System memory 1020 may be configured to store program instructions 1100 or data 1110. Program instructions 1100 may be executable by a processor (e.g., one or more of processors 1010a-1010n) to implement one or more embodiments of the present techniques. Instructions 1100 may include modules of computer program instructions for implementing one or more techniques described herein with regard to various processing modules. Program instructions may include a computer program (which in certain forms is known as a program, software, software application, script, or code). A computer program may be written in a programming language, including compiled or interpreted languages, or declarative or procedural languages. A computer program may include a unit suitable for use in a computing environment, including as a stand-alone program, a module, a component, or a subroutine. A computer program may or may not correspond to a file in a file system. A program may be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program may be deployed to be executed on one or more computer processors located locally at one site or distributed across multiple remote sites and interconnected by a communication network.

System memory 1020 may include a tangible program carrier having program instructions stored thereon. A tangible program carrier may include a non-transitory computer readable storage medium. A non-transitory computer readable storage medium may include a machine readable storage device, a machine readable storage substrate, a memory device, or any combination thereof. Non-transitory computer readable storage medium may include non-volatile memory (e.g., flash memory, ROM, PROM, EPROM, EEPROM memory), volatile memory (e.g., random access memory (RAM), static random access memory (SRAM), synchronous dynamic RAM (SDRAM)), bulk storage memory (e.g., CD-ROM and/or DVD-ROM, hard-drives), or the like. System memory 1020 may include a non-transitory computer readable storage medium that may have program instructions stored thereon that are executable by a computer processor (e.g., one or more of processors 1010a-1010n) to cause the subject matter and the functional operations described herein. A memory (e.g., system memory 1020) may include a single memory device and/or a plurality of memory devices (e.g., distributed memory devices). Instructions or other program code to provide the functionality described herein may be stored on a tangible, non-transitory computer readable media. In some cases, the entire set of instructions may be stored concurrently on the media, or in some cases, different parts of the instructions may be stored on the same media at different times.

I/O interface 1050 may be configured to coordinate I/O traffic between processors 1010a-1010n, system memory 1020, network interface 1040, I/O devices 1060, and/or other peripheral devices. I/O interface 1050 may perform protocol, timing, or other data transformations to convert data signals from one component (e.g., system memory 1020) into a format suitable for use by another component (e.g., processors 1010a-1010n). I/O interface 1050 may include support for devices attached through various types of peripheral buses, such as a variant of the Peripheral Component Interconnect (PCI) bus standard or the Universal Serial Bus (USB) standard.

Embodiments of the techniques described herein may be implemented using a single instance of computer system 1000 or multiple computer systems 1000 configured to host different portions or instances of embodiments. Multiple computer systems 1000 may provide for parallel or sequential processing/execution of one or more portions of the techniques described herein.

Those skilled in the art will appreciate that computer system 1000 is merely illustrative and is not intended to limit the scope of the techniques described herein. Computer system 1000 may include any combination of devices or software that may perform or otherwise provide for the performance of the techniques described herein. For example, computer system 1000 may include or be a combination of a cloud-computing system, a data center, a server rack, a server, a virtual server, a desktop computer, a laptop computer, a tablet computer, a server device, a client device, a mobile telephone, a personal digital assistant (PDA), a mobile audio or video player, a game console, a vehicle-mounted computer, or a Global Positioning System (GPS), or the like. Computer system 1000 may also be connected to other devices that are not illustrated, or may operate as a stand-alone system. In addition, the functionality provided by the illustrated components may in some embodiments be combined in fewer components or distributed in additional components. Similarly, in some embodiments, the functionality of some of the illustrated components may not be provided or other additional functionality may be available.

Those skilled in the art will also appreciate that while various items are illustrated as being stored in memory or on storage while being used, these items or portions of them may be transferred between memory and other storage devices for purposes of memory management and data integrity. Alternatively, in other embodiments some or all of the software components may execute in memory on another device and communicate with the illustrated computer system via inter-computer communication. Some or all of the system components or data structures may also be stored (e.g., as instructions or structured data) on a computer-accessible medium or a portable article to be read by an appropriate drive, various examples of which are described above. In some embodiments, instructions stored on a computer-accessible medium separate from computer system 1000 may be transmitted to computer system 1000 via transmission media or signals such as electrical, electromagnetic, or digital signals, conveyed via a communication medium such as a network or a wireless link. Various embodiments may further include receiving, sending, or storing instructions or data implemented in accordance with the foregoing description upon a computer-accessible medium. Accordingly, the present techniques may be practiced with other computer system configurations.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g. within a data center or geographically), or otherwise differently organized. The functionality described herein may be provided by one or more processors of one or more computers executing code stored on a tangible, non-transitory, machine readable medium. In some cases, notwithstanding use of the singular term “medium,” the instructions may be distributed on different storage devices associated with different computing devices, for instance, with each computing device having a different subset of the instructions, an implementation consistent with usage of the singular term “medium” herein. In some cases, third party content delivery networks may host some or all of the information conveyed over networks, in which case, to the extent information (e.g., content) is said to be supplied or otherwise provided, the information may provided by sending instructions to retrieve that information from a content delivery network.

The reader should appreciate that the present application describes several independently useful techniques. Rather than separating those techniques into multiple isolated patent applications, applicants have grouped these techniques into a single document because their related subject matter lends itself to economies in the application process. But the distinct advantages and aspects of such techniques should not be conflated. In some cases, embodiments address all of the deficiencies noted herein, but it should be understood that the techniques are independently useful, and some embodiments address only a subset of such problems or offer other, unmentioned benefits that will be apparent to those of skill in the art reviewing the present disclosure. Due to costs constraints, some techniques disclosed herein may not be presently claimed and may be claimed in later filings, such as continuation applications or by amending the present claims. Similarly, due to space constraints, neither the Abstract nor the Summary of the Invention sections of the present document should be taken as containing a comprehensive listing of all such techniques or all aspects of such techniques.

It should be understood that the description and the drawings are not intended to limit the present techniques to the particular form disclosed, but to the contrary, the intention is to cover all modifications, equivalents, and alternatives falling within the spirit and scope of the present techniques as defined by the appended claims. Further modifications and alternative embodiments of various aspects of the techniques will be apparent to those skilled in the art in view of this description. Accordingly, this description and the drawings are to be construed as illustrative only and are for the purpose of teaching those skilled in the art the general manner of carrying out the present techniques. It is to be understood that the forms of the present techniques shown and described herein are to be taken as examples of embodiments. Elements and materials may be substituted for those illustrated and described herein, parts and processes may be reversed or omitted, and certain features of the present techniques may be utilized independently, all as would be apparent to one skilled in the art after having the benefit of this description of the present techniques. Changes may be made in the elements described herein without departing from the spirit and scope of the present techniques as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an element” or “a element” includes a combination of two or more elements, notwithstanding use of other terms and phrases for one or more elements, such as “one or more.” The term “or” is, unless indicated otherwise, non-exclusive, i.e., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Similarly, reference to “a computer system” performing step A and “the computer system” performing step B can include the same computing device within the computer system performing both steps or different computing devices within the computer system performing steps A and B. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. Limitations as to sequence of recited steps should not be read into the claims unless explicitly specified, e.g., with explicit language like “after performing X, performing Y,” in contrast to statements that might be improperly argued to imply sequence limitations, like “performing X on items, performing Y on the X'ed items,” used for purposes of making claims more readable rather than specifying sequence. Statements referring to “at least Z of A, B, and C,” and the like (e.g., “at least Z of A, B, or C”), refer to at least Z of the listed categories (A, B, and C) and do not require at least Z units in each category. Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device. Features described with reference to geometric constructs, like “parallel,” “perpendicular/orthogonal,” “square”, “cylindrical,” and the like, should be construed as encompassing items that substantially embody the properties of the geometric construct, e.g., reference to “parallel” surfaces encompasses substantially parallel surfaces. The permitted range of deviation from Platonic ideals of these geometric constructs is to be determined with reference to ranges in the specification, and where such ranges are not stated, with reference to industry norms in the field of use, and where such ranges are not defined, with reference to industry norms in the field of manufacturing of the designated feature, and where such ranges are not defined, features substantially embodying a geometric construct should be construed to include those features within 15% of the defining attributes of that geometric construct. The terms “first”, “second”, “third,” “given” and so on, if used in the claims, are used to distinguish or otherwise identify, and not to show a sequential or numerical limitation. As is the case in ordinary usage in the field, data structures and formats described with reference to uses salient to a human need not be presented in a human-intelligible format to constitute the described data structure or format, e.g., text need not be rendered or even encoded in Unicode or ASCII to constitute text; images, maps, and data-visualizations need not be displayed or decoded to constitute images, maps, and data-visualizations, respectively; speech, music, and other audio need not be emitted through a speaker or decoded to constitute speech, music, or other audio, respectively. Computer implemented instructions, commands, and the like are not limited to executable code and can be implemented in the form of data that causes functionality to be invoked, e.g., in the form of arguments of a function or API call. To the extent bespoke noun phrases (and other coined terms) are used in the claims and lack a self-evident construction, the definition of such phrases may be recited in the claim itself, in which case, the use of such bespoke noun phrases should not be taken as invitation to impart additional limitations by looking to the specification or extrinsic evidence.

In this patent, to the extent any U.S. patents, U.S. patent applications, or other materials (e.g., articles) have been incorporated by reference, the text of such materials is only incorporated by reference to the extent that no conflict exists between such material and the statements and drawings set forth herein. In the event of such conflict, the text of the present document governs, and terms in this document should not be given a narrower reading in virtue of the way in which those terms are used in other materials incorporated by reference.

The present techniques will be better understood with reference to the following enumerated embodiments:
1. A structure for a micro-light-emitting diode, comprising: a substrate layer; an n-type gallium nitride (GaN) layer disposed above the substrate layer, the n-type GaN layer comprising a donor selected from silicon and germanium; an active region disposed above the n-type GaN layer, the active region comprising: a multiple-quantum-well stack of indium gallium nitride (InGaN) quantum wells separated by barrier layers, each quantum well having a thickness of less than or equal to 3 nanometers and at least one of the quantum wells having an indium mole fraction greater than 0.10; an electron blocking layer disposed above the active region, the electron blocking layer comprising an aluminum-containing group-III nitride; a p-type GaN layer disposed above the electron blocking layer; and an epitaxial optical reflector disposed relative to the active region comprising at least one of: a distributed Bragg reflector formed of III-nitride quarter-wave layers below the active region, and a distributed Bragg reflector formed of III-nitride quarter-wave layers above the active region.
2. The structure of embodiment 1, wherein: the substrate is selected from silicon, sapphire, silicon carbide, and GaN; the substrate has a crystallographic orientation selected from c-plane, m-plane, and semi-polar orientations; the electron blocking layer has a thickness less than 100 nanometers; the p-type GaN layer has a thickness between 100 and 200 nm; and the p-type GaN layer comprises magnesium.
3. The structure of embodiment 1, wherein the active region further comprises a quantum-dot superlattice structure comprising indium-containing III-nitride islands within a III-nitride matrix with interlayer spacings in a sub-10-nanometer range.
4. The structure of embodiment 1, further comprising a polarization-management structure adjacent the active region comprising at least one of a graded-composition cladding and a dislocation-reduction superlattice.
5. The structure of embodiment 1, further comprising a top-contact architecture comprising one of: a p-type contact cap over the p-type GaN layer having a thickness within a sub-hundred-nanometer range, or a tunnel-junction stack comprising a heavily doped p++/n++ junction configured to provide a low-resistance top contact.
6. The structure of embodiment 1, wherein: the structure is patterned into a pixel having a lateral dimension less than 15 micrometers, the structure is driven by direct current modulation, and the structure is configured to exhibit a small-signal 3-dB modulation bandwidth greater than or equal to 2 GHz at approximately 25° C. and an energy per bit of 3 pJ/bit or less at a bit-error rate of approximately 10⁻¹².
7. The structure of embodiment 1, wherein the multiple-quantum-well stack comprises 3 to 5 wells separated by barriers having a thickness in a range of 2 nm to 8 nm, with an asymmetry in barrier thickness between a lower barrier and an upper barrier of at least 0.5 nm.
8. The structure of embodiment 1, wherein the active region is implemented in an array of III-nitride nanowires disposed on a non-polar or semipolar GaN seed layer, the nanowires formed by selective-area epitaxy or vapor-liquid-solid initiation and comprising axial or core-shell p-i-n junctions with an InGaN active region.
9. The structure of embodiment 8, wherein: the nanowire array has a pitch in a range of 0.5 μm to 5 μm, each nanowire having a lateral dimension in a range of 50 nm to 300 nm and a height in a range of 0.5 μm to 5 μm, n-type segments include donors selected from silicon and germanium at 5×10⁻¹⁷ cm⁻³ to 5×10⁻¹⁹ cm⁻³, p-type segments include magnesium at 5×10⁻¹⁸ cm⁻³ to 5×10⁻¹⁹ cm⁻³, and the structure further comprises a transparent conductor over the array comprises a film selected from indium tin oxide, indium zinc oxide, or fluorine-doped tin oxide with a thickness in a range of 50 nm to 200 nm, the array aligned to a waveguide interface selected from a butt coupler or a grating coupler.
10. The structure of embodiment 1, wherein the structure is configured for optical interconnect between compute and memory devices within a multi-processor module.
11. A pixel structure of a micro-light-emitting diode device comprising: a mesa defined by etching through a p-type GaN layer of an epitaxial stack and at least partially into an InGaN active region of the epitaxial stack, the mesa having a lateral dimension less than 15 micrometers, wherein sidewalls of the mesa have a tapered, conical, or parabolic profile; isolation trenches extending through the epitaxial stack laterally bounding the mesa; a conformal dielectric passivation layer on the sidewalls of the mesa; a transparent conductive current-spreading layer over the mesa; a reflector over the transparent conductive current-spreading layer; an adhesion/barrier stack between the reflector and the transparent conductive current-spreading layer; a planarization dielectric surrounding the mesa, the planarization dielectric including vias to the transparent conductive current-spreading layer and to an n-type GaN layer of the epitaxial stack; a p-contact metallization coupled to the transparent conductive current-spreading layer; an n-contact metallization coupled to the n-type GaN layer, the n-contact at least partly surrounding the mesa; an anti-reflection coating disposed on the reflector; and an emission-collimation feature aligned to the mesa comprising one of: a micro-lens, or a surface-textured region configured to increase coupling of emitted light.
12. The structure of embodiment 11, wherein: the transparent conductive current-spreading layer comprises indium tin oxide deposited on the mesa to a thickness of 50 nm to 200 nm, the transparent conductive current-spreading layer has a sheet resistance of less than 100 ohms per square and an optical transmittance greater than 85% at an emission wavelength of 400 to 900 nm, and the reflector is disposed directly on the transparent conductive current-spreading layer.
13. The structure of embodiment 11, wherein the reflector further comprises at least one of a metallic mirror and a distributed Bragg reflector.
14. The structure of embodiment 11, wherein the n-contact metallization further comprises a guard-ring segment.
15. The structure of embodiment 11, wherein: the structure is aligned to and optically coupled to a planar silicon-nitride waveguide having a numerical aperture of 0.1-0.3 and an emitter-waveguide separation of 100 μm or less; and the structure is configured to exhibit a coupling efficiency of 50% or more into a guided mode and support an aggregate edge throughput density greater than 10 Tbps/mm without serializer-deserializer circuitry.
16. The structure of embodiment 11, further comprising an asymmetric cavity with an output interface having an effective reflectivity less than ten percent and a back reflector having an effective reflectivity greater than ninety percent.
17. The structure of embodiment 16, wherein: the cavity has a length in a range of 8 μm to 9 μm measured along a principal feedback axis, the output interface comprises an anti-reflection stack of one to three dielectric layers and an index-transition spacer having a refractive index in a range of 1.3 to 1.6, the back reflector comprises a dielectric distributed Bragg reflector of 6 to 12 alternating pairs selected from SiO₂/TiO₂ or SiN/SiO₂ with an effective reflectivity of at least 95%, and the output interface has an effective reflectivity in a range of 1% to 8%.
18. A method of fabricating a structure for a micro-light-emitting diode, the method comprising: obtaining a crystalline substrate selected from silicon, sapphire, silicon carbide, and GaN, the substrate having a surface orientation selected from c-plane, m-plane, or semi-polar orientations; epitaxially forming an n-type GaN layer doped with a donor selected from silicon and germanium on the crystalline substrate, the n-type GaN layer having a thickness of 0.5 μm to 5.0 μm; epitaxially forming an active region comprising a plurality of InGaN quantum wells, wherein each quantum well has a thickness less than or equal to 3 nanometers, and at least one of the quantum wells has an indium mole fraction greater than 0.10; depositing an electron blocking layer adjacent the active region, the electron blocking layer having a thickness less than 100 nanometers; and epitaxially forming a p-type GaN layer comprising magnesium over the electron blocking layer.
19. The method of embodiment 18, further comprising: patterning and etching the structure to form a pixel mesa having a lateral dimension less than 15 micrometers and sidewalls having a tapered, conical, or parabolic profile; depositing a conformal dielectric passivation on the sidewalls of the pixel mesa; forming a transparent conductive current-spreading layer over the pixel mesa and patterning the layer to define a p-contact region electrically coupled to the p-type GaN layer; forming an n-contact to the n-type GaN layer, the n-contact at least partly surrounding the pixel mesa; and depositing a reflector over the transparent current-spreading layer.
20. The method of embodiment 18, wherein epitaxially forming an active region comprising a plurality of InGaN quantum wells comprises steps for controlling well thickness and indium composition during growth.

What is claimed is:

1. A structure for a micro-light-emitting diode, comprising:
a substrate layer;
an n-type gallium nitride (GaN) layer disposed above the substrate layer, the n-type GaN layer comprising a donor selected from silicon and germanium;
an active region disposed above the n-type GaN layer, the active region comprising:
a multiple-quantum-well stack of indium gallium nitride (InGaN) quantum wells separated by barrier layers, each quantum well having a thickness of less than or equal to 3 nanometers and at least one of the quantum wells having an indium mole fraction greater than 0.10;
an electron blocking layer disposed above the active region, the electron blocking layer comprising an aluminum-containing group-III nitride;
a p-type GaN layer disposed above the electron blocking layer; and
an epitaxial optical reflector disposed relative to the active region comprising at least one of:
a distributed Bragg reflector formed of III-nitride quarter-wave layers below the active region, and
a distributed Bragg reflector formed of III-nitride quarter-wave layers above the active region.

2. The structure of claim 1, wherein:
the substrate is selected from silicon, sapphire, silicon carbide, and GaN;
the substrate has a crystallographic orientation selected from c-plane, m-plane, and semi-polar orientations;
the electron blocking layer has a thickness less than 100 nanometers;
the p-type GaN layer has a thickness between 100 and 200 nm;
the p-type GaN layer comprises magnesium; and
the active region further comprises a quantum-dot superlattice structure comprising indium-containing III-nitride islands within a III-nitride matrix with interlayer spacings in a sub-10-nanometer range.

3. The structure of claim 1, further comprising a monolithic gallium nitride lens formed from a portion of a GaN material of an epitaxial stack that includes the n-type GaN layer and the p-type GaN layer, the monolithic GaN lens disposed on an emission side of the structure and having a curved surface profile.

4. The structure of claim 1, further comprising a polarization-management structure adjacent the active region comprising at least one of a graded-composition cladding and a dislocation-reduction superlattice.

5. The structure of claim 1, further comprising a top-contact architecture comprising one of:
a p-type contact cap over the p-type GaN layer having a thickness within a sub-hundred-nanometer range, or
a tunnel-junction stack comprising a heavily doped p++/n++ junction configured to provide a low-resistance top contact.

6. The structure of claim 1, wherein the active region is implemented in an array of III-nitride nanowires disposed on a non-polar or semipolar GaN seed layer, the nanowires comprising an InGaN active region.

7. The structure of claim 1, wherein the multiple-quantum-well stack comprises 3 to 5 wells separated by barriers having a thickness in a range of 2 nm to 8 nm, with an asymmetry in barrier thickness between a lower barrier and an upper barrier of at least 0.5 nm.

8. The structure of claim 1, wherein the active region is implemented in an array of III-nitride nanowires disposed on a non-polar or semipolar GaN seed layer, the nanowires formed by selective-area epitaxy or vapor-liquid-solid initiation and comprising axial or core-shell p-i-n junctions with an InGaN active region.

9. The structure of claim 8, wherein:
the nanowire array has a pitch in a range of 0.5 μm to 5 μm, each nanowire having a lateral dimension in a range of 50 nm to 300 nm and a height in a range of 0.5 μm to 5 μm,
n-type segments include donors selected from silicon and germanium at 5×10⁻¹⁷ cm⁻³ to 5×10⁻¹⁹ cm⁻³,
p-type segments include magnesium at 5×10⁻¹⁸ cm⁻³ to 5×10⁻¹⁹ cm⁻³, and
the structure further comprises a transparent conductor over the array comprises a film selected from indium tin oxide, indium zinc oxide, or fluorine-doped tin oxide with a thickness in a range of 50 nm to 200 nm, the array aligned to a waveguide interface selected from a butt coupler or a grating coupler.

10. The structure of claim 1, wherein the structure is configured for optical interconnect between compute and memory devices within a multi-processor module.

11. A pixel structure of a micro-light-emitting diode device comprising:
a mesa defined by etching through a p-type GaN layer of an epitaxial stack and at least partially into an InGaN active region of the epitaxial stack, the mesa having a lateral dimension less than 15 micrometers, wherein sidewalls of the mesa have a tapered, conical, or parabolic profile;
isolation trenches extending through the epitaxial stack laterally bounding the mesa;
a conformal dielectric passivation layer on the sidewalls of the mesa;
a transparent conductive current-spreading layer over the mesa;
a reflector over the transparent conductive current-spreading layer;
an adhesion/barrier stack between the reflector and the transparent conductive current-spreading layer;
a planarization dielectric surrounding the mesa, the planarization dielectric including vias to the transparent conductive current-spreading layer and to an n-type GaN layer of the epitaxial stack;
a p-contact metallization coupled to the transparent conductive current-spreading layer;
an n-contact metallization coupled to the n-type GaN layer, the n-contact at least partly surrounding the mesa;
an anti-reflection coating disposed on the reflector; and
an emission-collimation feature aligned to the mesa comprising one of:
a micro-lens, or
a surface-textured region configured to increase coupling of emitted light.

12. The structure of claim 11, wherein:
the transparent conductive current-spreading layer comprises indium tin oxide deposited on the mesa to a thickness of 50 nm to 200 nm,
the transparent conductive current-spreading layer has a sheet resistance of less than 100 ohms per square and an optical transmittance greater than 85% at an emission wavelength of 400 to 900 nm, and
the reflector is disposed directly on the transparent conductive current-spreading layer.

13. The structure of claim 11, wherein the reflector further comprises at least one of a metallic mirror and a distributed Bragg reflector.

14. The structure of claim 11, wherein the n-contact metallization further comprises a guard-ring segment.

15. The structure of claim 11, wherein:
the structure is aligned to and optically coupled to a planar silicon-nitride waveguide having a numerical aperture of 0.1-0.3 and an emitter-waveguide separation of 100 μm or less; and
the structure is configured to exhibit a coupling efficiency of 50% or more into a guided mode and support an aggregate edge throughput density greater than 10 Tbps/mm without serializer-deserializer circuitry.

16. The structure of claim 11, further comprising an asymmetric cavity with an output interface having an effective reflectivity less than ten percent and a back reflector having an effective reflectivity greater than ninety percent, wherein the asymmetric cavity is configured, under forward bias within a selected non-lasing window, to emit super-luminescent output in an amplified spontaneous emission regime.

17. The structure of claim 16, wherein:
the cavity has a length in a range of 8 μm to 9 μm measured along a principal feedback axis,
the output interface comprises an anti-reflection stack of one to three dielectric layers and an index-transition spacer having a refractive index in a range of 1.3 to 1.6,
the back reflector comprises a dielectric distributed Bragg reflector of 6 to 12 alternating pairs selected from SiO₂/TiO₂ or SiN/SiO₂ with an effective reflectivity of at least 95%, and
the output interface has an effective reflectivity in a range of 1% to 8%.

18. A method of fabricating a structure for a micro-light-emitting diode, the method comprising:
obtaining a crystalline substrate selected from silicon, sapphire, silicon carbide, and GaN, the substrate having a surface orientation selected from c-plane, m-plane, or semi-polar orientations;
epitaxially forming an n-type GaN layer doped with a donor selected from silicon and germanium on the crystalline substrate, the n-type GaN layer having a thickness of 0.5 μm to 5.0 μm;
epitaxially forming an active region comprising a plurality of InGaN quantum wells, wherein each quantum well has a thickness less than or equal to 3 nanometers, and at least one of the quantum wells has an indium mole fraction greater than 0.10;
depositing an electron blocking layer adjacent the active region, the electron blocking layer having a thickness less than 100 nanometers; and
epitaxially forming a p-type GaN layer comprising magnesium over the electron blocking layer.

19. The method of claim 18, further comprising:
patterning and etching the structure to form a pixel mesa having a lateral dimension less than 15 micrometers and sidewalls having a tapered, conical, or parabolic profile;
depositing a conformal dielectric passivation on the sidewalls of the pixel mesa;
forming a transparent conductive current-spreading layer over the pixel mesa and patterning the layer to define a p-contact region electrically coupled to the p-type GaN layer;
forming an n-contact to the n-type GaN layer, the n-contact at least partly surrounding the pixel mesa; and
depositing a reflector over the transparent current-spreading layer.

20. The method of claim 18, wherein epitaxially forming an active region comprising a plurality of InGaN quantum wells comprises steps for controlling well thickness and indium composition during growth.
